(19) United States
(12) Patent Application Publication
(10) Pub. No.: US 2025/0142902 A1
(43) Pub. Date: May 1, 2025

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Kuo-Chiang TSAI, Hsinchu City (TW); Jeng-Ya YEH, New Taipei City (TW); Mu-Chi CHIANG, Hsinchu City (TW)

(73) Assignee: TAIWAN SEMICONDUCTOR MANUFACTURING COMPANY, LTD., Hsinchu (TW)

(21) Appl. No.: 18/494,060

(22) Filed: Oct. 25, 2023

(51) Int. Cl. H01L 29/06; H01L 21/8238; H01L 27/092; H01L 29/423; H01L 29/66; H01L 29/775; H01L 29/78

(52) U.S. Cl. CPC H10D 62/121; H10D 30/014; H10D 30/024; H10D 30/43; H10D 30/6211; H10D 30/6735; H10D 64/017; H10D 84/0167; H10D 84/017; H10D 84/0193; H10D 84/038; H10D 84/853

(57) ABSTRACT

A method includes forming a transistor over a substrate, the transistor comprising a channel region, a gate structure over the channel region, and a plurality of source/drain regions on opposite sides of the channel region; forming a source/drain contact over one of the source/drain regions; forming a source/drain via over the source/drain contact, wherein from a top view, the source/drain via has a T-shaped profile, the source/drain via has a first portion extending in a lengthwise direction of the channel region, and a second portion extending in a lengthwise direction of the gate structure.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate perspective views of an example fin-like field-effect transistor (FinFET) device and a nano-FET device, respectively, in accordance with some embodiments of the present disclosure.

FIGS. 2A and 2F-2K illustrates schematic top views of layouts of semiconductor structures in accordance with some embodiments of the present disclosure.

FIGS. 2B-2E illustrate schematic cross-sectional views taken along lines B1-B1, C1-C1, D1-D1, and E1-E1 as shown in FIG. 2A.

FIGS. 3A-18D illustrate schematic views of intermediate stages in the formation of a semiconductor structure over a substrate in accordance with some embodiments.

FIG. 19 is a schematic diagram of an electronic design automation (EDA) system in accordance with some embodiments of the present disclosure.

FIG. 20 is a block diagram of an IC manufacturing system and an IC manufacturing flow associated therewith, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present disclosure are directed to, but not otherwise limited to, a fin-like field-effect transistor (FinFET) device. The FinFET device, for example, may be a complementary metal-oxide-semiconductor (CMOS) device including a P-type metal-oxide-semiconductor (PMOS) FinFET device and an N-type metal-oxide-semiconductor (NMOS) FinFET device. The following disclosure will continue with one or more FinFET examples to illustrate various embodiments of the present disclosure. It is understood, however, that the application should not be limited to a particular type of device, except as specifically claimed.

The fins may be patterned by any suitable method. For example, the fins may be patterned using one or more photolithography processes, including double-patterning or multi-patterning processes. The double-patterning or the multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

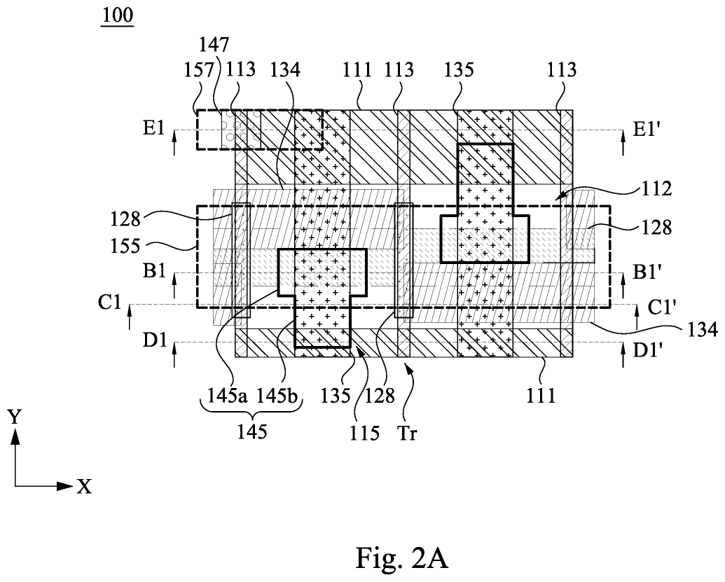

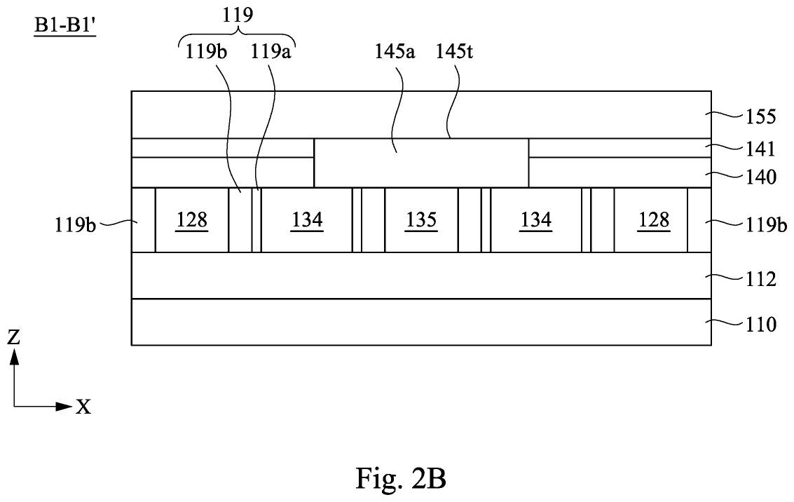

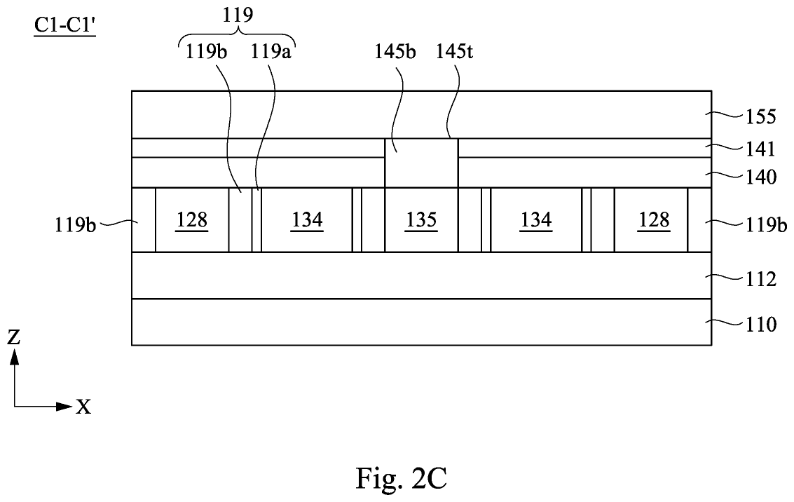

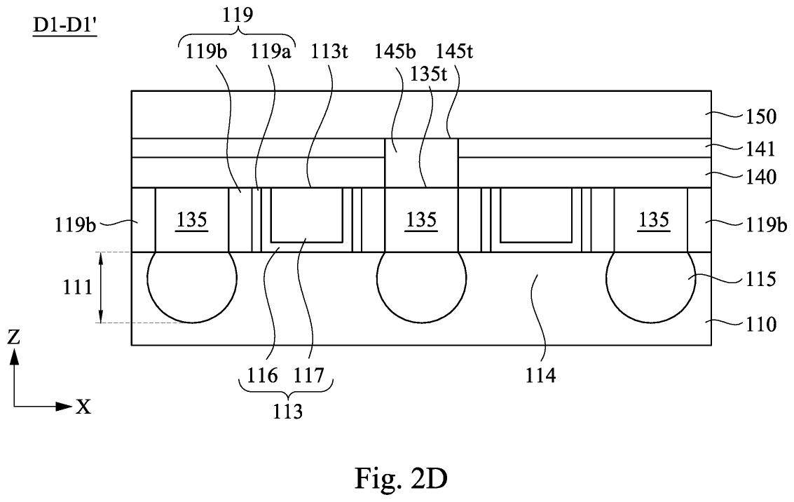

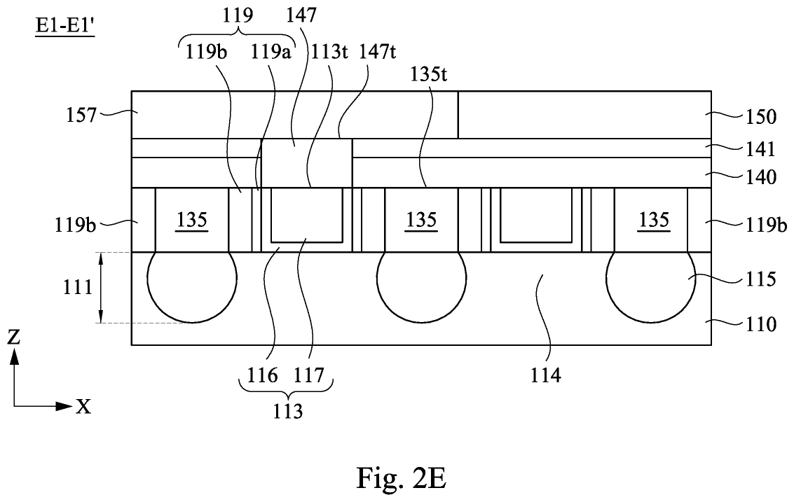

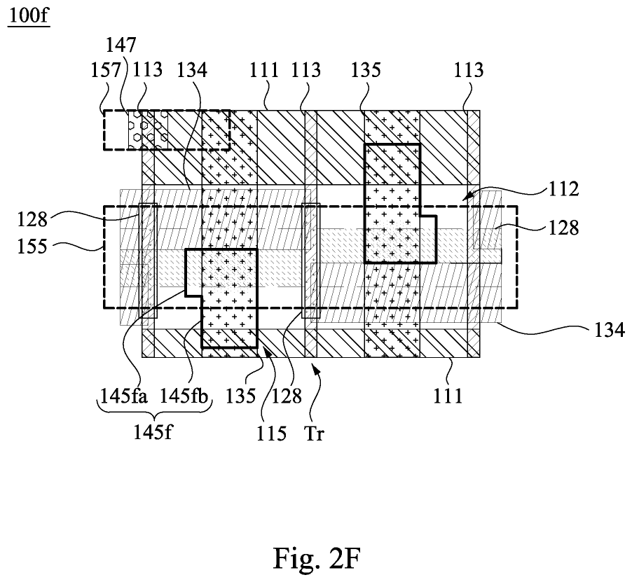

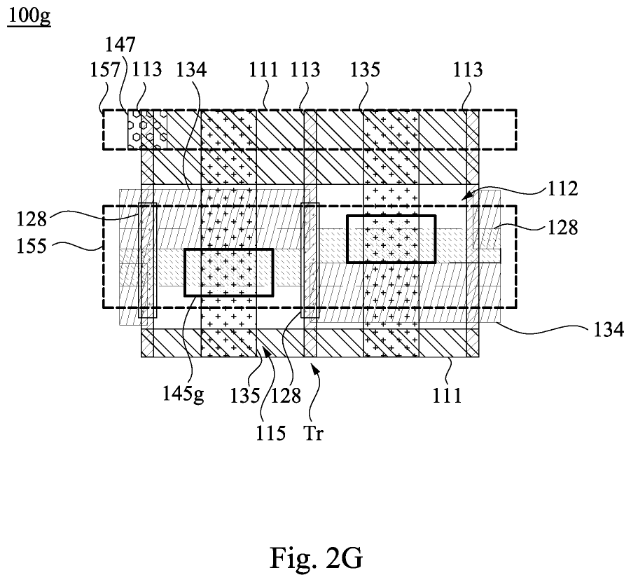

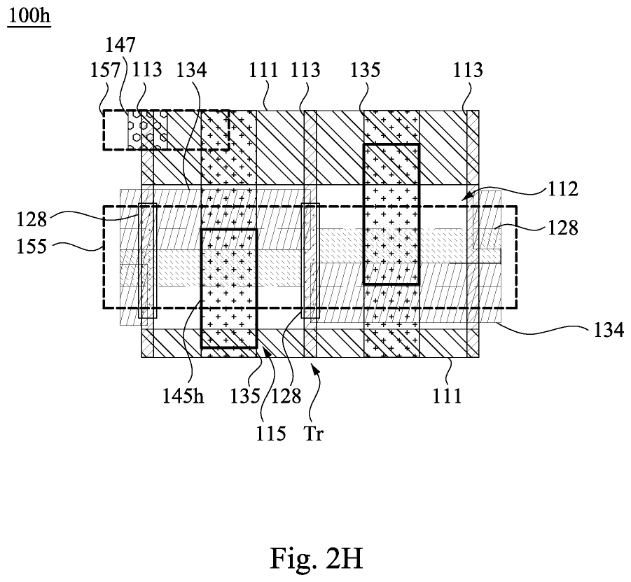

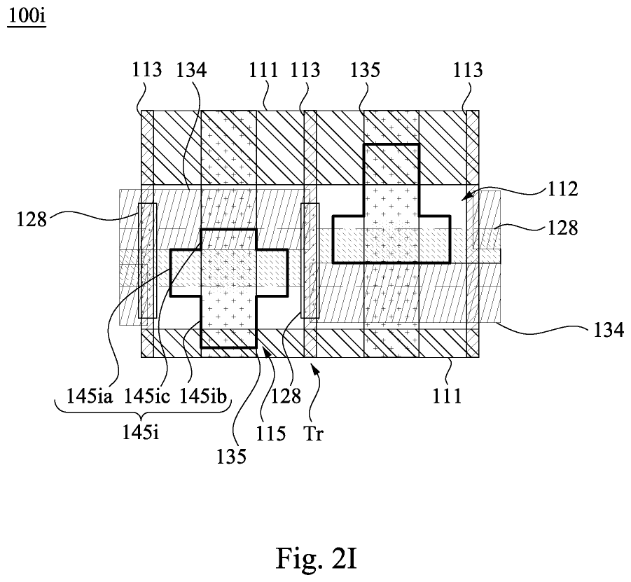

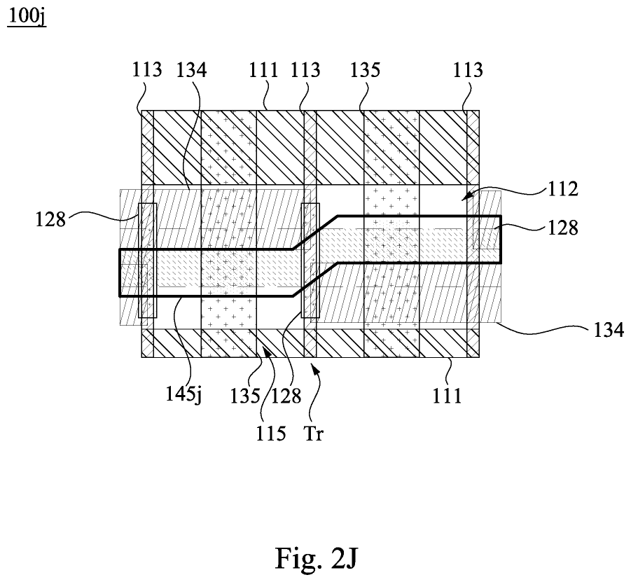

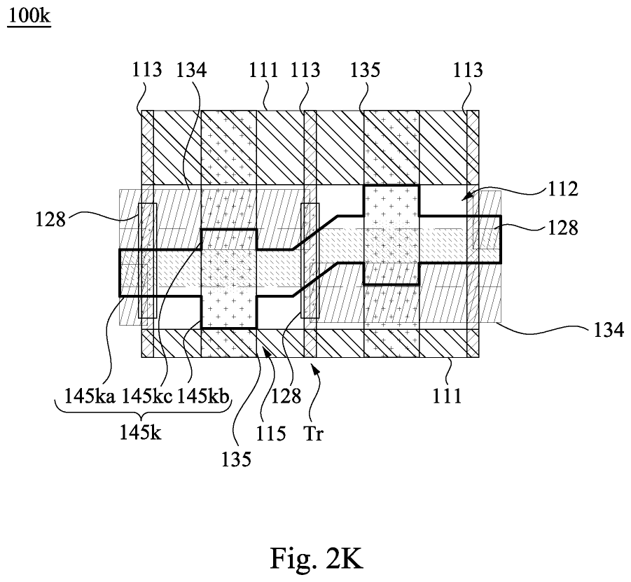

Throughout the evolution of integrated circuits (ICs), the functional density (i.e., the number of interconnected devices per chip area) has generally increased while geometry size (i.e., the smallest component (or line) that can be created using a fabrication process) has decreased. This scaling down process presents some challenges, such as concerning RC time delays, which stem from contact resistance and capacitance complexities. Therefore, the present disclosure in various embodiments provides a source/drain via over the source/drain region of the transistor that has a T-shaped top view profile (see FIG. 2A), so as to expand the volume of source/drain via. By increasing the volume of the source/drain via, the source/drain via can reduce the contact resistance, such that Rc of source/drain via can be reduced by such as at least about 50%. In addition, by enlarging the volume of the source/drain via, the distance between the gate structure and the source/drain contact can be further modified. Due to the increased volume of the source/drain via, the modification can reduce the overlap area and distance between the gate structure and the source/drain contact, leading to a reduced effective capacitance (Ceff), such as at least about 3% Ceff reduction in FEOL. Furthermore, by enlarging the volume of the source/drain via, the spatial relation and alignment of metal lines over the source/drain via can be further modified. Similar to the FEOL, due to the increased volume of the source/drain via, the modification can reduce the overlap area and distance between the metal lines, leading to a reduced effective capacitance (Ceff), such as at least about 3% Ceff reduction in BEOL.

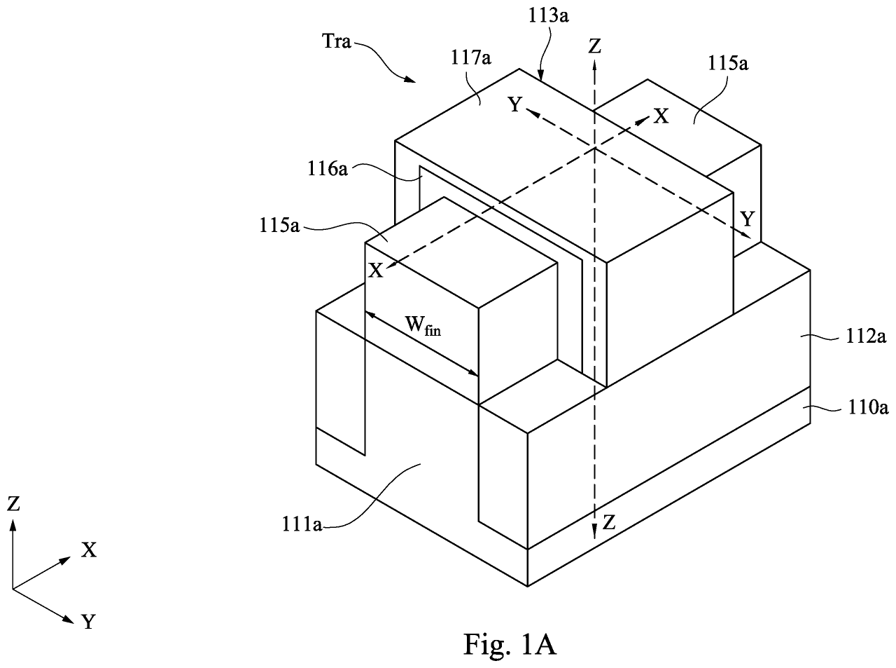

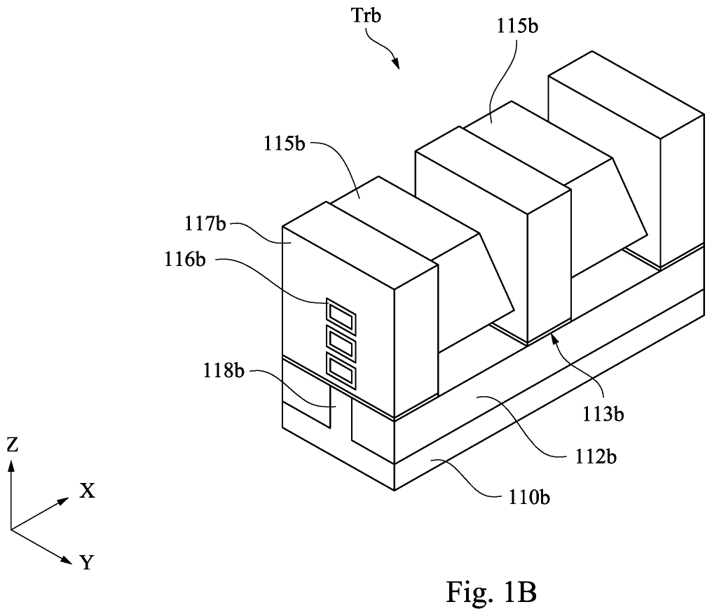

Reference is made to FIGS. 1A and 1B. FIGS. 1A and 1B illustrate perspective views of an example fin-like field-effect transistor (FinFET) Tra and an example nano-FET transistor Trb, respectively, in accordance with some embodiments of the present disclosure, and the transistor Tra, the transistor Trb, and/or other suitable devices can be applied to the semiconductor structure 100 as shown in FIGS. 2A-2K with a source/drain via having a T-shaped top view profile.

In some embodiments, the transistor Tr formed in FIGS. 2A-2K can employ the FinFET device (e.g. transistor Tra shown in FIG. 1A). The FinFET device can be a non-planar multi-gate transistor that is built over the substrate 110a, for example a silicon substrate. The substrate 110a may be made of a suitable elemental semiconductor, such as silicon, diamond or germanium; a suitable alloy or compound semiconductor, such as Group-IV compound semiconductors (silicon germanium (SiGe), silicon carbide (SiC), silicon germanium carbide (SiGeC), GeSn, SiSn, SiGeSn), Group III-V compound semiconductors (e.g., gallium arsenide, indium gallium arsenide InGaAs, indium arsenide, indium phosphide, indium antimonide, gallium arsenic phosphide, or gallium indium phosphide), or the like. Further, the substrate 110a may include an epitaxial layer (epi-layer), which may be strained for performance enhancement, and/or may include a silicon-on-insulator (SOI) structure. An N-type well and a P-type well are formed in the substrate 110a. A P-type FinFET is formed over the N-type well, and an N-type FinFET is formed over the P-type well.

A thin silicon-containing “fin-like” structure (hereinafter referred to as a “fin”) forms an active region 111a of the transistor Tra. The fin-like structure extends along an X-direction and protrudes upwardly out of the dielectric isolation structure 112a as shown in FIG. 1A. The fin-like structure has a fin width W_{fin} measured along a Y-direction that is orthogonal to the X-direction. A portion of the fin-like structure being wrapped around by gate structures 113a can serve as channel regions (e.g., channel regions 114 as shown in FIGS. 2D and 2E) of the FinFET devices. The effective channel length of the FinFET device is determined by the dimensions of the fin-like structure. In some embodiments, the channel region 114 (see FIGS. 2D and 2E) can be interchangeably referred to as a channel pattern, a fin structure, or a fin pattern. As shown in FIG. 1A, the transistor Tra can include the channel region in the active region 111a underlying the gate structures 113a, the source/drain regions 115a on opposite sides of the channel region and connected to the channel region, and the gate structure 113a wrapping around the channel region.

The dielectric isolation structure 112a, such as a shallow trench isolation (STI) structure, formed over the substrate 110a. The dielectric isolation structure 112a can define and electrically isolate the active region 111a of the transistors Tra. Formation of the dielectric isolation structure 112a includes patterning the semiconductor substrate 110a to form one or more trenches in the substrate 110a by using suitable photolithography and etching techniques, depositing one or more dielectric materials (e.g., silicon oxide) to completely fill the trenches in the substrate 110a, followed by a planarization process (e.g., chemical mechanical polish (CMP) process) to level the dielectric isolation structure 112a with the active region 111a. The dielectric materials of the dielectric isolation structure 112a may be deposited using a high density plasma chemical vapor deposition (HDP-CVD), a low-pressure CVD (LPCVD), sub-atmospheric CVD (SACVD), a flowable CVD (FCVD), spin-on coating, and/or the like, or a combination thereof. After the deposition, an anneal process or a curing process may be performed, especially when the dielectric isolation structure 112a is formed using flowable CVD. In some embodiments, the dielectric isolation structure 112a can be further recessed (e.g., by an etch back process) to fall below the top surfaces of the active region 111a, such that the active region 111a protrude above the top surface of the recessed dielectric isolation structure 112a to form fin-like structures, which in turn allows for forming FinFET devices over the active region 111a.

The gate structure 113a extends across the active region 111a along the Y-direction perpendicular to the X-direction. The gate structure 113a can have a strip shape from the top view and are thus interchangeably referred to as metal gate strips in this context. In some embodiments, the gate structure 113a can be interchangeably referred to as gates, metal gates, gate layers, gate strip, or gate patterns. In some embodiments, the gate structure 113a can be a functional high-k metal gate (HKMG) gate structure. The gate structure 113a can be formed using a same gate-last process flow (interchangeably referred to as gate replacement flow), which will be explained in greater detail below. As a result of the gate-last process flow, the gate structures 113a can include one or more gate electrode layers 117a and a gate dielectric layer 116a lining a bottom surface and sidewalls of the one or more gate electrode layers 117a, so that the gate dielectric layer 116a can have a U-shaped cross section as illustrated in FIGS. 2D and 2E.

The source/drain regions 115a can be formed in the active region 111a. The source/drain regions 115a can be doped semiconductor regions located on opposite sides of the corresponding gate structure 113a. In some embodiments, the source/drain regions 115a include p-type dopants or impurities such as boron for forming functional p-type FETs in the active regions 111a. In some other embodiments, the source/drain regions 115a include n-type dopants or impurities such as phosphorus for forming functional n-type FETs in the active regions 111a. In some embodiments, the source/drain regions 115a may be epitaxially grown regions having crystalline semiconductor material and formed by a selective epitaxial growth (SEG) process. The crystalline semiconductor material may be an elemental semiconductor (e.g., Si, or Ge, or the like), or an alloy semiconductor (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 10¹⁴ cm⁻² to 10¹⁶ cm⁻²) of n-type or p-type dopants may be introduced into source/drain regions 115a either in situ during SEG, or by an ion implantation process performed after the SEG, or by a combination thereof.

As shown in FIG. 1B, the transistor Tr formed in FIGS. 2A-2K can employ the nano-FET (e.g. transistor Trb shown in FIG. 1B). The nano-FET may be nanosheet field-effect transistors (NSFETs), nanowire field-effect transistors (NWFETs), gate-all-around field-effect transistors (GAAFETs), or the like. The transistor Trb include active regions 111b (e.g., nanostructures, nanosheets, nanowires, or the like) over a fin 118b on a substrate 110b, with the active regions 111b acting as channel regions (e.g., channel regions 114 as shown in FIGS. 2D and 2E) for the transistor Trb. In some embodiments, the active regions 111b may include p-type nanostructures, n-type nanostructures, or a combination thereof and extend along an X-direction. In some embodiments, the active regions 111b can be interchangeably referred to as channel patterns, channel regions, nanostructures, nanosheets, nanowires. In some embodiments, the transistor Trb can include the active region 111b, the source/drain regions 115b on opposite sides of the active region 111b and connected to the active region 111b, and the gate structure 113b wrapping around the active region 111b.

A dielectric isolation structure 112b, such as a shallow trench isolation (STI), can be formed to laterally surround the fin 118b. In some embodiments, material and manufacturing method of the dielectric isolation structure 112b, the substrate 110b, and the source/drain regions 115b may be substantially the same as that of the dielectric isolation structure 112a, the substrate 110a, and the source/drain regions 115a as shown in FIG. 1A, and the related detailed descriptions may refer to the foregoing paragraphs, and are not described again herein.

In some embodiments, the gate structures 113b may include one or more gate electrode layer 117b and a gate dielectric layer 116b. The gate dielectric layers 116b can be formed over top surfaces of the fin 118b and along top surfaces, sidewalls, and bottom surfaces of the active regions 111b. The gate electrode layers 117b are formed over the gate dielectric layer 116b. In some embodiments, the gate dielectric layer 116b may include a dielectric material having a k-value greater than about 7.0, such as a metal oxide or a silicate of hafnium, aluminum, zirconium, lanthanum, manganese, barium, titanium, lead, and combinations thereof. Although a single-layered gate dielectric layer 116b is illustrated in FIG. 1B, the gate dielectric layer 116b may include any number of interfacial layers and any number of main layers. In some embodiments, the gate electrode layer 117b may include a metal-containing material such as titanium nitride, titanium oxide, tungsten, cobalt, ruthenium, aluminum, combinations thereof, multi-layers thereof, or the like. Although a single-layered gate electrode layer 117b is illustrated in FIG. 1B, the gate electrode layer 117b may include any number of work function tuning layers, any number of barrier layers, any number of glue layers, and a fill material. In some embodiments, the gate electrode layer 117b may be made of a material selected from a group including TiN, TaN, TiAl, TiAlN, TaAl, TaAlN, TaAlC, TaCN, WNC, Co, Ni, Pt, W, or combinations thereof.

In some embodiments, inner spacers (not shown) can be formed between the source/drain regions 115b and the corresponding gate structures 113b and serve to isolate the gate structures 113b from source/drain regions 115b. The inner spacer 219 may be a low-k dielectric material, such as SiO₂, silicon nitride (SiN), silicon carbonoxide (SiCO), silicon carbonnitride (SiCN), silicon oxycarbonnitride (SiOCN). The inner spacer 219 can be formed using CVD, including LPCVD and PECVD, PVD, ALD, or other suitable processes.

Reference is made to FIGS. 2A-2K. FIGS. 2A and 2F-2K illustrates schematic top views of layouts of the semiconductor structure 100 in accordance with some embodiments of the present disclosure. FIGS. 2B, 2C, 2D, and 2E are cross-sectional views taken along lines B1-B1′, C1-C1′, D1-D1′, and E1-E1′ as shown in FIG. 2A.

As shown in FIGS. 2A-2E, the semiconductor structure 100 has a source/drain via 145 over a source/drain region 115 of the transistor Tr. The source/drain via 145 can have a T-shaped top view profile (see FIG. 2A), so as to expand the volume of source/drain via 145. By increasing the volume of the source/drain via 145, the increased volume can be available for current to flow increases. Given that the resistance is inversely proportional to the volume, a larger source/drain via 145 will reduce the contact resistance, such that Rc of source/drain via 145 can be reduced by such as at least about 50%. In addition, the front-end-of-line (FEOL) can refer to the steps involved in forming the active devices in semiconductor manufacturing. By enlarging the volume of the source/drain via 145, the distance between the gate structure 113 and the source/drain contact 135 can be further modified. Capacitance is directly proportional to the surface area of the plates and inversely proportional to the distance between them. Due to the increased volume of the source/drain via 145, the modification can reduce the overlap area and distance between the gate structure 113 and the source/drain contact 135, leading to a reduced effective capacitance (Ceff), such as at least about 3% Ceff reduction in FEOL.

Furthermore, the back-end-of-line (BEOL) process can refer to the steps involved in forming the interconnects (e.g., the metal lines 155 and 157) between the devices. By enlarging the volume of the source/drain via 145, the spatial relation and alignment of metal lines 155 and 157 can be further modified. Similar to the FEOL, due to the increased volume of the source/drain via 145, the modification can reduce the overlap area and distance between the metal lines 155 and 157, leading to a reduced effective capacitance (Ceff), such as at least about 3% Ceff reduction in BEOL.

In some embodiments, to enlarge the volume of the source/drain via 145, the semiconductor structure 100 can provide the T-shaped top view profile for the source/drain via 145. This T-shaped top view profile can maximize the area available for current flow and to optimize the device's electrical properties. A first one of the steps to achieve the T-shaped view profile for the source/drain via 145 can involve enlarging the critical dimension of the dielectric region 128 (e.g., cut metal gate (CMG)). By expanding this dimension, more space is made available for the source/drain via 145 to adopt its T-shaped view profile. A second one of the steps to achieve the T-shaped view profile for the source/drain via 145 can involve removing its dummy section of the metal layer 157 connecting the gate via 147. By removing this dummy section, the length of the metal layer 157 is shortened. This not only saves space but also allows for the adjacent source/drain via 145 to expand its volume. As the dummy section of the metal layer 157 is removed, it can provide more space for the source/drain via 145 to extend, enhancing its volume. Therefore, by combining the CMG critical dimension enlargement with the optimization of the metal layers 155 and 157, the source/drain via 145 can be structured to have a T-shaped top view profile. This shape allows for a larger cross-sectional area for current to flow, which directly contributes to reductions in resistance and effective capacitances.

As shown in FIGS. 2A-2E, a substrate 110 (see FIGS. 2D and 2E) is provided for forming transistor Tr with the source/drain via 145 having the T-shaped top view profile. One or more dielectric isolation structure 112 (see FIGS. 2A-2C) can be formed in the substrate 210 to define active regions 111 (see FIGS. 2A, 2D, and 2E). The gate structure 113 (see FIGS. 2A, 2D, and 2E) can be formed over the active region 111 (see FIGS. 2A, 2D, and 2E). The gate structure 113 may include a gate dielectric layer 116 and a gate metal layer 117 over the gate dielectric layer 116. In some embodiments, if the transistor Tr formed over the substrate 110 is a FinFET (e.g. transistor Tra shown in FIG. 1A), a fin-like” structure (e.g., active region 111a shown in FIG. 1A) can be formed in the substrate 110. In some embodiments, if the transistor Tr formed over the substrate 110 is a nano-FET (e.g. transistor Trb shown in FIG. 1B), a plurality of semiconductor sheets (e.g., active regions 111b shown in FIG. 1B) can be formed in the substrate 110 and can be interchangeably referred to as a vertically stacked multiple channels (sheets), and thus the gate dielectric layer 116 and the gate electrode layer 117 can be further formed in the regions between the semiconductor sheets to wrap around the semiconductor sheets in the substrate 110.

The dielectric regions 128 (see FIGS. 2A-2C) can be formed in of the gate structures 113. In some embodiments, each dielectric region 128 is a gate-cut structure for the gate structure 113, and the gate-cut structure is formed by a cut metal gate (CMG) process. In some embodiments, the dielectric region 128 can be interchangeably referred to a gate end dielectric. In some embodiments, the dielectric region 128 can continuously extend across the gate structures 113, and portions of the dielectric region 128 between the longitudinal ends of adjacent two gate structures 113 can have greater dimensions than other portions of the dielectric region 128 between the source/drain contacts 135 along the lengthwise direction of the gate structure 113. In some embodiments, the dielectric region 128 may be formed of or comprise SiO₂, SiOC, SiOCN, or the like, or combinations thereof. In some embodiments, the dielectric region 128 may be made of a nitride-based material, such as Si₃N₄, or a carbon-based material, such as SiOCN, or combinations thereof. In some embodiments, the dielectric region 128 may be made of a material having a dielectric constant greater than about 9 (e.g., high dielectric constant (high-k) material). For example, the dielectric region 128 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The dielectric region 128 may be formed of a homogenous material, or may have a composite structure including more than one layer. In some embodiments, the dielectric region 128 can be interchangeably referred to as a dielectric structure.

In some embodiments, material and manufacturing method of the substrate 110, the active region 111, the gate structure 113, the gate dielectric layer 116, and the gate electrode layer 117 may be substantially the same as that of the substrates 110a and 110b, the active regions 111a and 111b, the gate structures 113a and 113b, the gate dielectric layers 116a and 116b, and the gate electrode layers 117a and 117b as shown in FIGS. 1A and 1B, and the related detailed descriptions may refer to the foregoing paragraphs, and are not described again herein.

Gate spacers 119 (see FIGS. 2B-2E) are then formed on opposite sidewalls of each gate structure 113 and on opposite sidewalls of each dielectric region 128. The gate spacer 119 can include a spacer layer 119a and a spacer layer 119b over the spacer layer 119a and having a different material than the spacer layer 119a. In some embodiments, the gate spacer 119 may include one or more dielectrics, such as silicon oxide, silicon nitride, silicon oxynitride, silicon carbide, silicon carbonitride, the like, or a combination thereof.

Source/drain regions 115 (see FIGS. 2D and 2E) are formed in the active region 111 (see FIGS. 2A, 2D, and 2E) and self-aligned to the gate spacers 119. A portion of the active region 111 (i.e., fin-like structure) between the corresponding source/drain regions 115 can serve as the channel regions 114 (see FIGS. 2D and 2E). In some embodiments, material and manufacturing method of the source/drain region 115 may be substantially the same as that of the source/drain regions 115a and 115b as shown in FIGS. 1A and 1B, and the related detailed descriptions may refer to the foregoing paragraphs, and are not described again herein. The dielectric regions 134 (see FIGS. 2A-2C) can be formed over the source/drain regions 115 to separate the source/drain contacts 135 (see FIGS. 2A-2D) on the source/drain regions 115. In some embodiments, each dielectric region 134 is a metal-like defined region (MD)-cut structure for forming the source/drain contact 135, and the MD-cut structure is formed by a cut metal-like defined region (CMD) process. In some embodiments, the dielectric region 134 can be interchangeably referred to as a dielectric structure. In some embodiments, the source/drain contacts 135 can be formed over the source/drain regions 115 and spaced apart from an adjacent one thereof by the dielectric region 134. The source/drain contacts 135 may include a metal-containing material such as titanium nitride, titanium oxide, tungsten, cobalt, ruthenium, aluminum, copper, combinations thereof, multi-layers thereof, or the like. The source/drain contact 135 can have a top surface 135t (see FIG. 2E) coplanar with a top surface 113t (see FIGS. 2D and 2E) of the gate structures 123. In other words, the top surface 135t of the source/drain contact 135 can be level with the top surface 123t (see FIGS. 2D and 2E) of the gate structure 113.

A contact etch stop layer (CESL) 140 (see FIGS. 2B-2E) and an ILD layer 141 (see FIGS. 2B-2E) can be formed over the gate structure 113 and the source/drain contacts 135. The CESL 140 may be formed of a dielectric material, such as silicon nitride, silicon oxide, silicon oxynitride, or the like, having a high etching selectivity from the etching of the ILD layer 141. The ILD layer 141 may be formed of phospho-silicate glass (PSG), boro-silicate glass (BSG), boron-doped phospho-silicate glass (BPSG), undoped silicate glass (USG), or the like. Other insulation materials formed by any acceptable process may be used.

The source/drain via 145 (see FIGS. 2A-2D) and a gate via 147 (see FIGS. 2A and 2E) can be formed over the source/drain contact 135 and the gate structure 113 and through the ILD layer 141 and the CESL 140. The source/drain via 145 and the gate via 147 may include a metal-containing material such as titanium nitride, titanium oxide, argentum (Ag), platinum (Pt), tungsten (W), cobalt (Co), ruthenium (Ru), RuCo, aluminum (Al), copper (Cu), Ru-alloy, W-alloy, molybdenum (Mo)-alloy, Cu-alloy, combinations thereof, multi-layers thereof, or the like.

In some embodiments, the source/drain via 145 (see FIG. 2A) can have the T-shaped top view profile and have a first portion 145a extending in the lengthwise direction of the active region 111 and a second portion 145b extending in the lengthwise direction of the gate structures 113. The first portion 145a (see FIG. 2B) of the source/drain via 145 can overlap with the source/drain contact 135 and the dielectric regions 118 on opposite sides of the source/drain contact 135. In some embodiments, the first portion 145a of the source/drain via 145 may have a lateral dimension (or width) greater than the lateral dimension of the source/drain contact and/or the lateral dimension of the dielectric region 128. The second portion 145b (see FIGS. 2C and 2D) of the source/drain via 145 can overlap the active region 111 and have a lateral dimension (or width) substantially the same as the lateral dimension of the source/drain contact 135. In some embodiments, the lateral dimension of the second portion 145b of the source/drain via 145 can be greater than or less than the lateral dimension of the source/drain contact 135. The lateral dimension of the first portion 145a is greater than the lateral dimension of the second portion 145b. The source/drain via 145 can have a top surface 145t (see FIGS. 2B-2D) level with a top surface 147t (see FIG. 2E) of the gate via 147.

An interconnect structure is formed over the source/drain via 145 and the conductive vias 147. The interconnect structure may include a metal line 155 (see FIGS. 2A-2C) and a metal line 157 (see FIGS. 2A and 2E) formed in a first metallization layer. The metal lines 155 and 157 are formed in an IMD (inter-metal dielectric) layer 150 (see FIGS. 2D and 2E). The metal layer 155 can be electrically connected to the source/drain via 145 and act as a power rail (PR), and the metal layer 157 can be electrically connected to the gate via 147. In some embodiments, materials of the metal lines 155 and 157 may include Cu, Co, Ru, Pt, Al, W, Ti, TaN, TiN, or any combinations thereof. In some embodiments, the IMD layer 150 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like.

Reference is made to FIG. 2F. While FIG. 2F show an embodiment of a semiconductor structure 100f with different cross-sectional view profiles than the semiconductor structure 100 in FIGS. 2A-2E. In addition, the present disclosure may repeat reference numerals and/or letters in the various examples. This repetition is for the purpose of simplicity and clarity and does not in itself dictate a relationship between the various embodiments and/or configurations discussed.

As shown in FIG. 2F, the difference between the embodiment in FIG. 2F and the embodiment in FIGS. 2A-2E is in that the source/drain via 145f can have the L-shaped top view profile, so as to expand the volume of source/drain via 145f, which in turn allows for a larger cross-sectional area for current to flow, which directly contributes to reductions in resistance and effective capacitances. The source/drain via 145f can have a first portion 145fa extending in the lengthwise direction of the active region 111 and a second portion 145fb extending in the lengthwise direction of the gate structures 113. The first portion 145fa of the source/drain via 145f can overlap with the source/drain contact 135 and the dielectric region 118 on one side of the source/drain contact 135. In some embodiments, the first portion 145fa of the source/drain via 145f may have a lateral dimension (or width) greater than the lateral dimension of the source/drain contact 135. The second portion 145fb of the source/drain via 145f can overlap the active region 111 and may have a lateral dimension (or width) substantially the same as the lateral dimension of the source/drain contact 135.

Reference is made to FIG. 2G. While FIG. 2G show an embodiment of a semiconductor structure 100g with different cross-sectional view profiles than the semiconductor structure 100 in FIGS. 2A-2E. In addition, the present disclosure may repeat reference numerals and/or letters in the various examples. This repetition is for the purpose of simplicity and clarity and does not in itself dictate a relationship between the various embodiments and/or configurations discussed.

As shown in FIG. 2G, the difference between the embodiment in FIG. 2G and the embodiment in FIGS. 2A-2E is in that the source/drain via 145g can have the rectangular top view profile, so as to expand the volume of source/drain via 145g, which in turn allows for a larger cross-sectional area for current to flow, which directly contributes to reductions in resistance and effective capacitances. The source/drain via 145g can extend in the lengthwise direction of the active region 111. The source/drain via 145g can overlap with the source/drain contact 135 and the dielectric regions 118 on opposite sides of the source/drain contact 135. In some embodiments, the source/drain via 145g may have a lateral dimension (or width) greater than the lateral dimension of the source/drain contact 135.

Reference is made to FIG. 2H. While FIG. 2H show an embodiment of a semiconductor structure 100h with different cross-sectional view profiles than the semiconductor structure 100 in FIGS. 2A-2E. In addition, the present disclosure may repeat reference numerals and/or letters in the various examples. This repetition is for the purpose of simplicity and clarity and does not in itself dictate a relationship between the various embodiments and/or configurations discussed.

As shown in FIG. 2H, the difference between the embodiment in FIG. 2H and the embodiment in FIGS. 2A-2E is in that the source/drain via 145h can have the rectangular top view profile, so as to expand the volume of source/drain via 145h, which in turn allows for a larger cross-sectional area for current to flow, which directly contributes to reductions in resistance and effective capacitances. The source/drain via 145h can extend in the lengthwise direction of the gate structure 113. The source/drain via 145h can overlap with the source/drain contact 135. The source/drain via 145h may have a width substantially the same as the width of the source/drain contact 135 in the lengthwise direction of the active region 111. The source/drain via 145h may can have a length overlapping with the active region 111 and greater than a dimension of the active region 111 in the lengthwise direction of the gate structure 113.

Reference is made to FIG. 2I. While FIG. 2I show an embodiment of a semiconductor structure 100i with different cross-sectional view profiles than the semiconductor structure 100 in FIGS. 2A-2E. In addition, the present disclosure may repeat reference numerals and/or letters in the various examples. This repetition is for the purpose of simplicity and clarity and does not in itself dictate a relationship between the various embodiments and/or configurations discussed.

As shown in FIG. 2I, the difference between the embodiment in FIG. 2I and the embodiment in FIGS. 2A-2E is in that the source/drain via 145i can have the cross shape top view profile, so as to expand the volume of source/drain via 145i, which in turn allows for a larger cross-sectional area for current to flow, which directly contributes to reductions in resistance and effective capacitances. The source/drain via 145f can have a first portion 145ia extending in the lengthwise direction of the active region 111, second and third portions 145ib and 145ic extending in the lengthwise direction of the gate structures 113.

As shown in FIG. 2I, the first portion 145ia of the source/drain via 145i can overlap with the source/drain contact 135 and the dielectric region 118 on one side of the source/drain contact 135. In some embodiments, the first portion 145ia of the source/drain via 145i may have a lateral dimension (or width) greater than the lateral dimension of the source/drain contact 135. The second portion 145ib of the source/drain via 145i can overlap the active region 111 and may have a lateral dimension (or width) substantially the same as the lateral dimension of the source/drain contact 135 in the lengthwise direction of the active region 111. The third portion 145ic of the source/drain via 145i is at a side of the source/drain via 145i opposite to the second portion 145ib. The third portion 145ic may have a lateral dimension (or width) substantially the same as the lateral dimension of the source/drain contact 135 in the lengthwise direction of the active region 111. In some embodiments, the lateral dimension of third portion 145ic can be substantially the same as the lateral dimension of the second portion 145ib in the lengthwise direction of the active region 111. In some embodiments, the lateral dimension of third portion 145ic can be greater than or less than the lateral dimension of the second portion 145ib in the lengthwise direction of the active region 111.

Reference is made to FIG. 2J. While FIG. 2J show an embodiment of a semiconductor structure 100j with different cross-sectional view profiles than the semiconductor structure 100 in FIGS. 2A-2E. In addition, the present disclosure may repeat reference numerals and/or letters in the various examples. This repetition is for the purpose of simplicity and clarity and does not in itself dictate a relationship between the various embodiments and/or configurations discussed.

As shown in FIG. 2J, the difference between the embodiment in FIG. 2J and the embodiment in FIGS. 2A-2E is in that the source/drain via 145j can have the a line shape (or a shake shape) top view profile, so as to expand the volume of source/drain via 145j, which in turn allows for a larger cross-sectional area for current to flow, which directly contributes to reductions in resistance and effective capacitances. The source/drain via 145j can continuously extend across a plurality of gate structures 113 and/or a plurality of source/drain contacts 135. The source/drain via 145j can overlap with the dielectric regions 118 on opposite sides of the source/drain contact 135. In some embodiments, the source/drain via 145j may have a lateral dimension (or width) greater than the lateral dimension of the source/drain contact 135 in the lengthwise direction of the active region 111.

Reference is made to FIG. 2K. While FIG. 2K show an embodiment of a semiconductor structure 100k with different cross-sectional view profiles than the semiconductor structure 100 in FIGS. 2A-2E. In addition, the present disclosure may repeat reference numerals and/or letters in the various examples. This repetition is for the purpose of simplicity and clarity and does not in itself dictate a relationship between the various embodiments and/or configurations discussed.

As shown in FIG. 2K, the difference between the embodiment in FIG. 2K and the embodiment in FIGS. 2A-2E is in that the source/drain via 145k can have a first portion 145ka having a line shaped top view profile and at least two protruding portions 145kb and 145kc on opposite sides of the first portion 145ka to form a centipede shape top view profile, so as to expand the volume of source/drain via 145k, which in turn allows for a larger cross-sectional area for current to flow, which directly contributes to reductions in resistance and effective capacitances.

As shown in FIG. 2K, the first portion 145ka of the source/drain via 145k can continuously extend across a plurality of gate structures 113 and/or a plurality of source/drain contacts 135. The source/drain via 145k can overlap with the dielectric regions 118 on opposite sides of the source/drain contact 135. In some embodiments, the source/drain via 145k may have a lateral dimension (or width) greater than the lateral dimension of the source/drain contact 135 in the lengthwise direction of the active region 111. The second portion 145kb of the source/drain via 145k can overlap the active region 111 and may have a lateral dimension (or width) substantially the same as the lateral dimension of the source/drain contact 135 in the lengthwise direction of the active region 111. The third portion 145kc of the source/drain via 145k is at a side of the source/drain via 145k opposite to the second portion 145kb. The third portion 145kc may have a lateral dimension (or width) substantially the same as the lateral dimension of the source/drain contact 135 in the lengthwise direction of the active region 111. In some embodiments, the lateral dimension of third portion 145kc can be substantially the same as the lateral dimension of the second portion 145kb in the lengthwise direction of the active region 111. In some embodiments, the lateral dimension of third portion 145kc can be greater than or less than the lateral dimension of the second portion 145kb in the lengthwise direction of the active region 111.

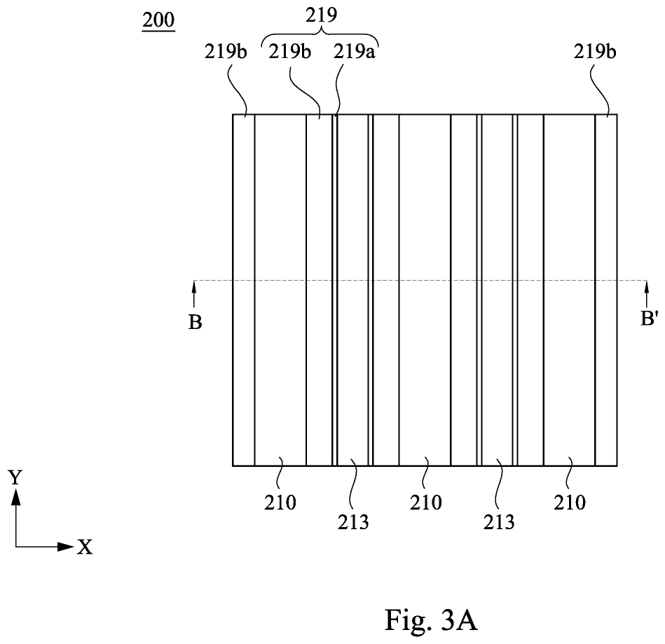

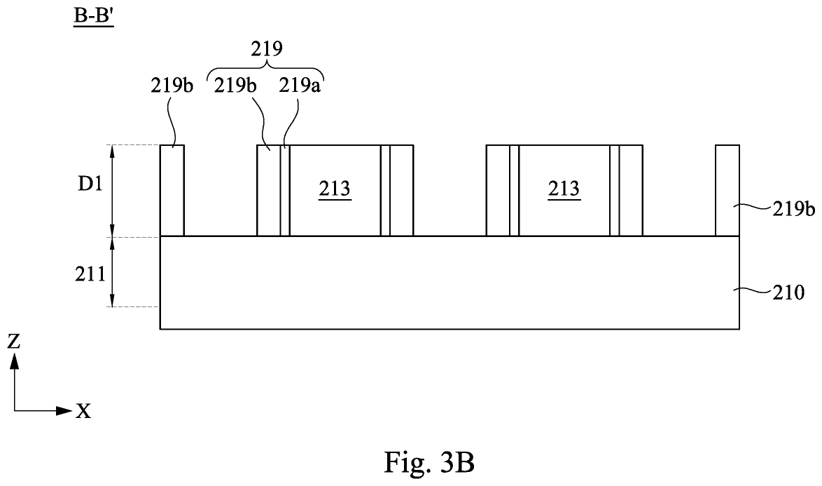

Reference is made to FIGS. 3A-18C. FIGS. 3A-18C illustrate schematic views of intermediate stages in the formation of a semiconductor structure 200 over a substrate in accordance with some embodiments. FIGS. 3A-18C illustrate schematic views of intermediate stages in the formation of a semiconductor structure 200 in accordance with some embodiments. In addition to the semiconductor structure 200, FIGS. 2A-18C depict X-axis, Y-axis, and Z-axis directions. It is understood that additional operations can be provided before, during, and after the processes shown by FIGS. 3A-18C, and some of the operations described below can be replaced or eliminated, for additional embodiments of the method. The order of the operations/processes may be interchangeable.

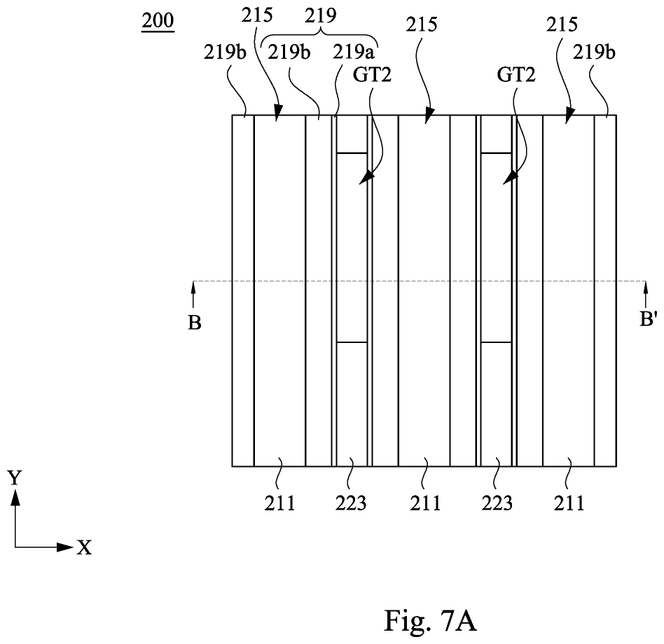

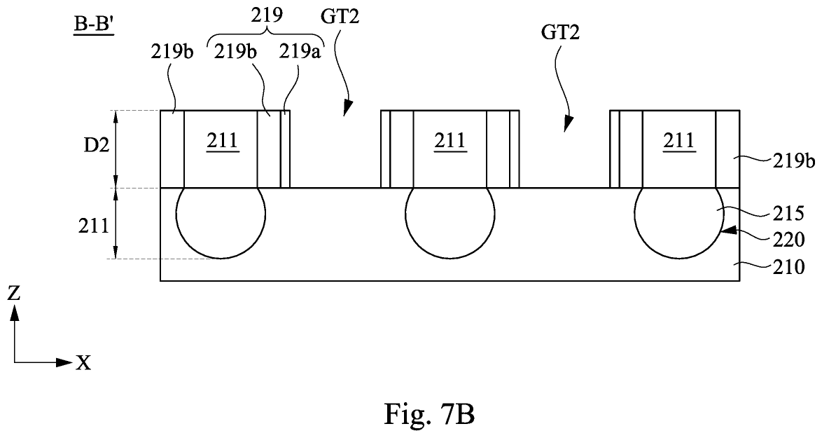

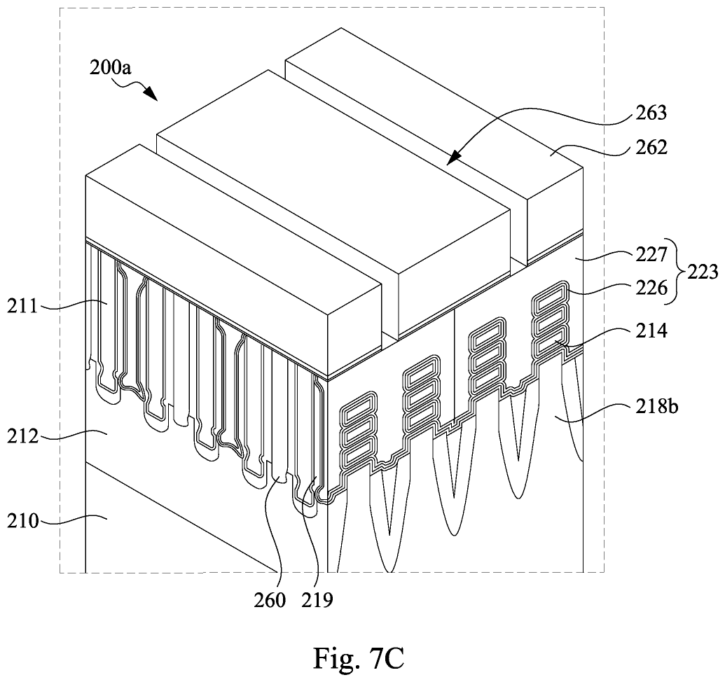

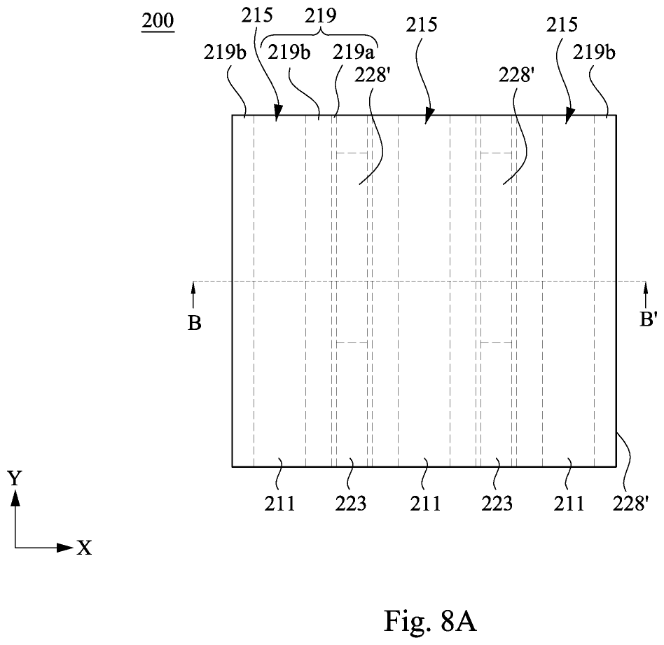

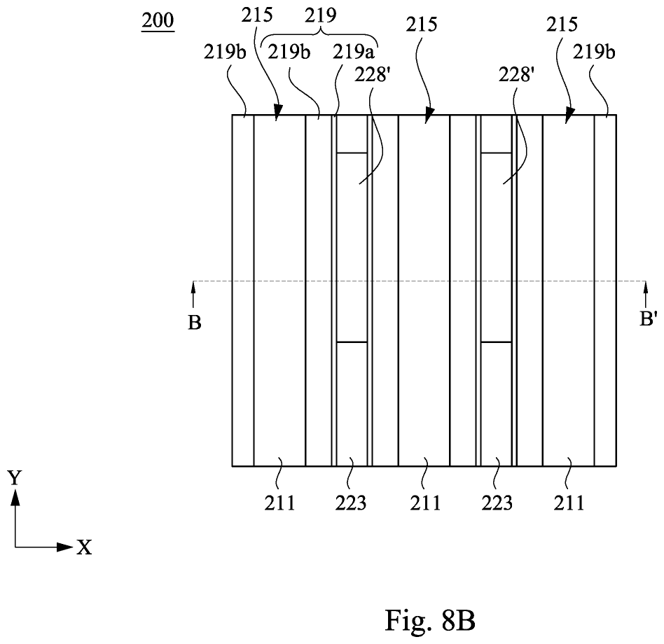

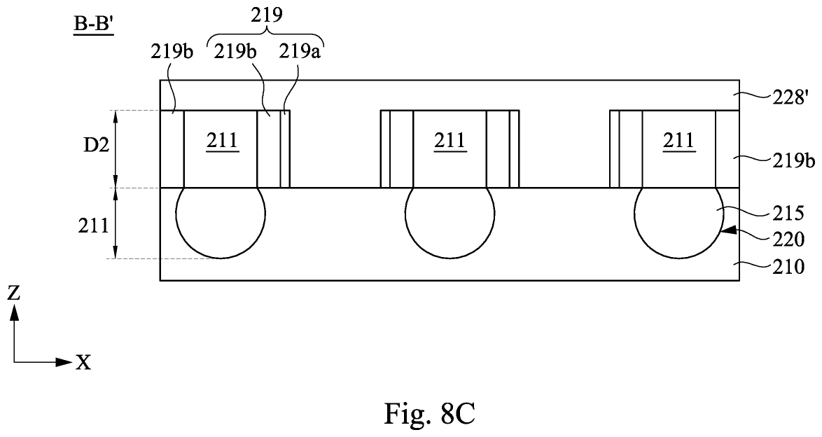

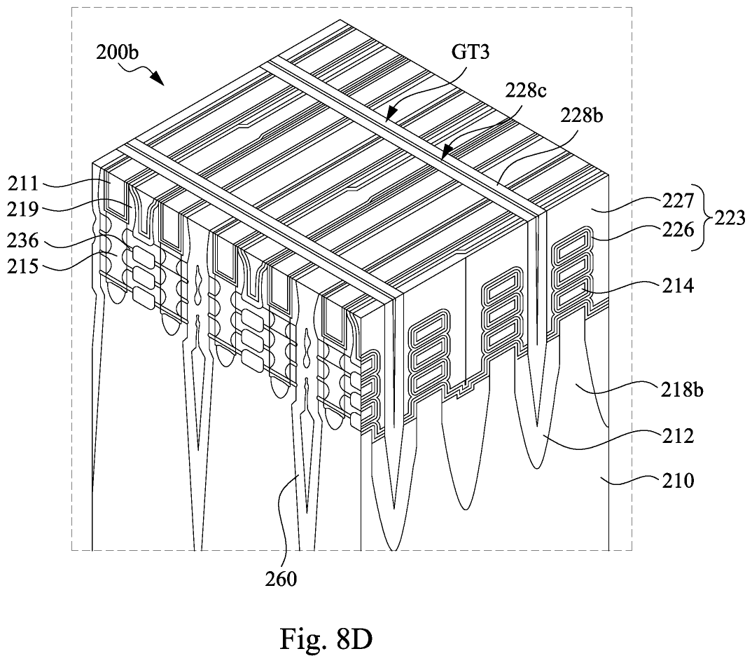

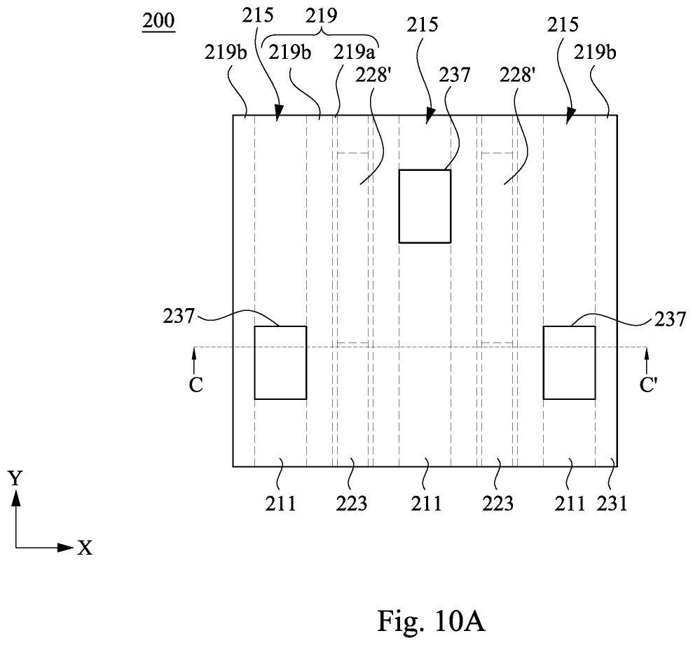

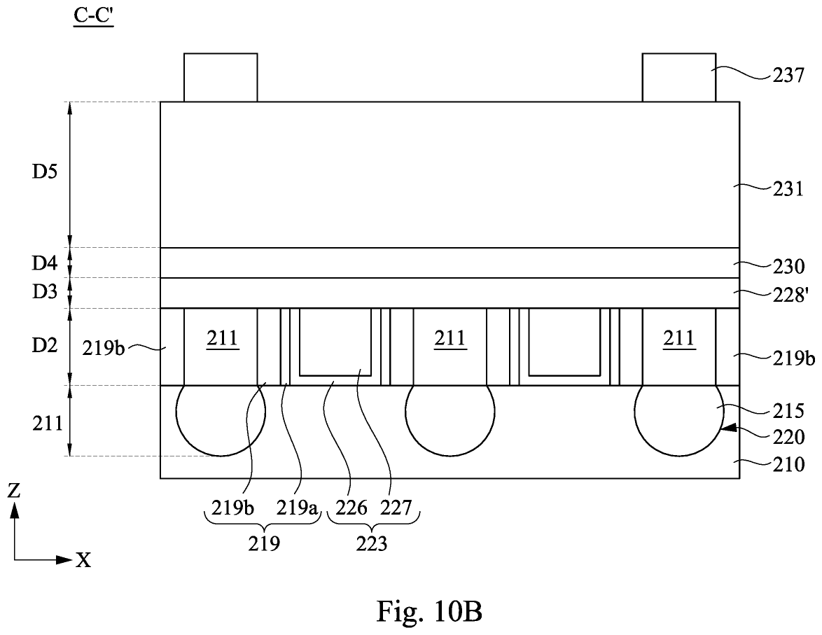

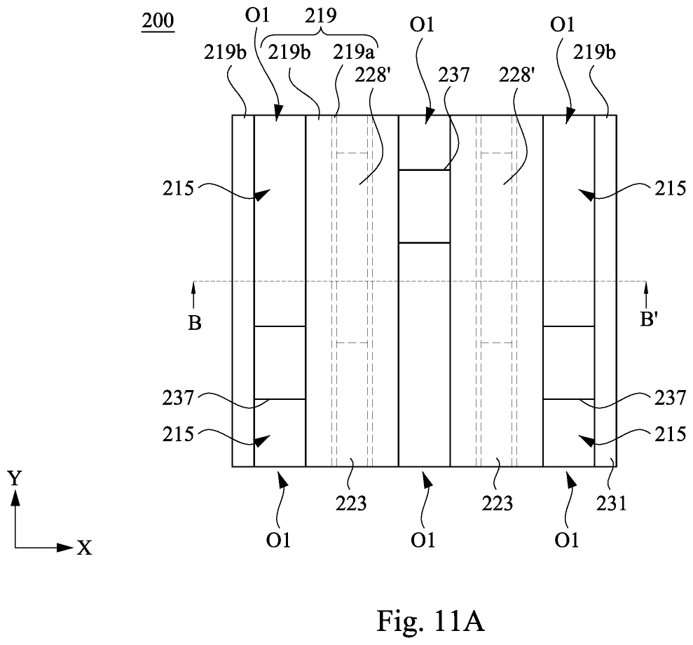

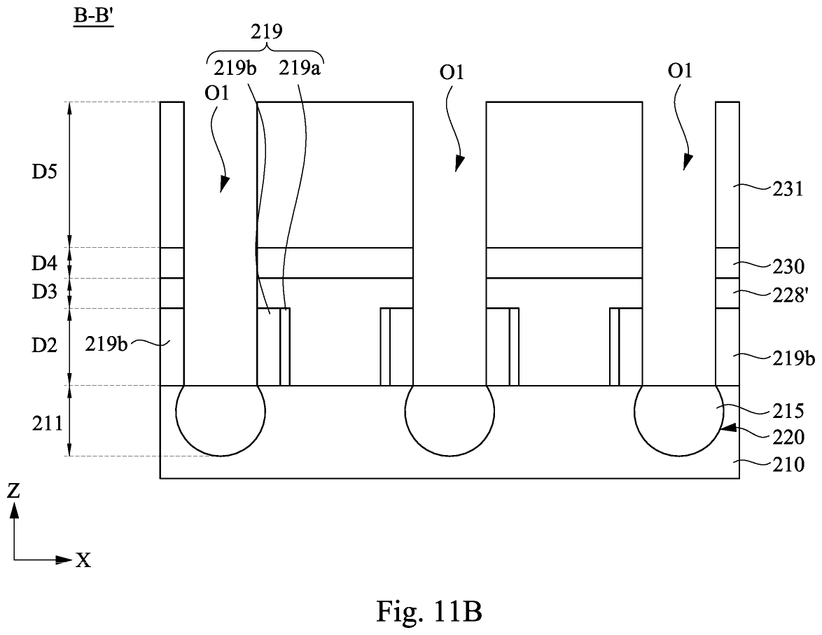

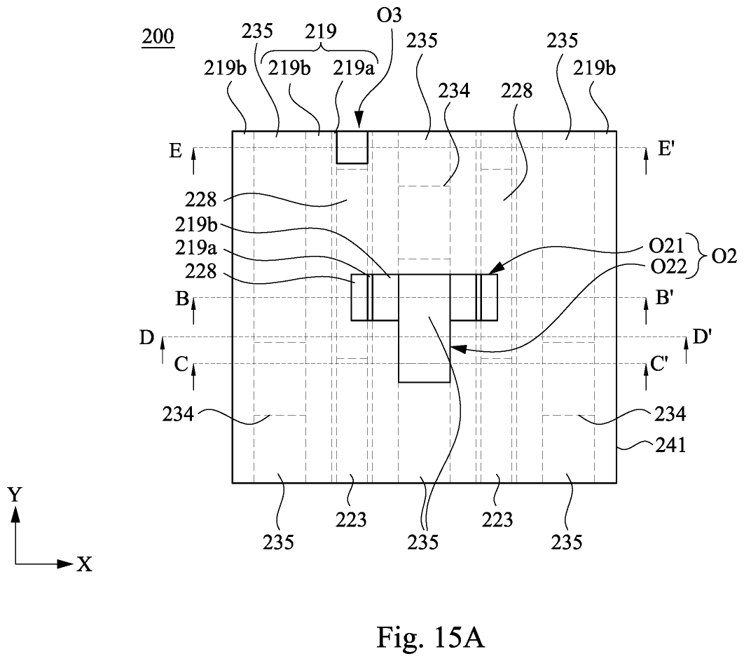

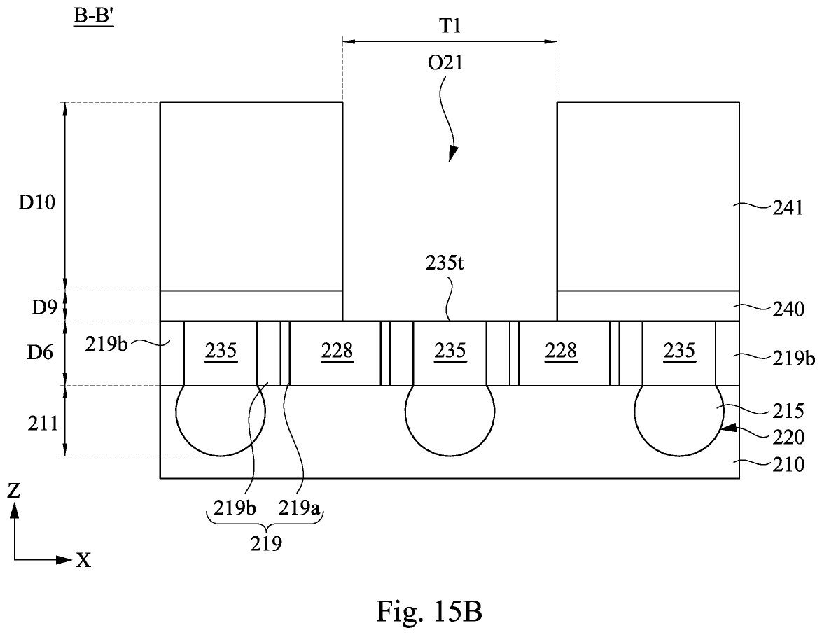

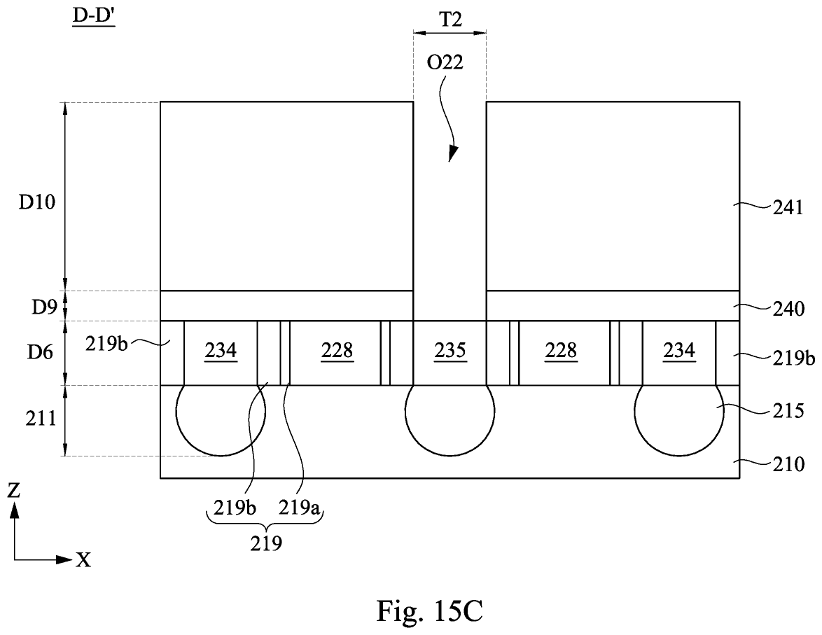

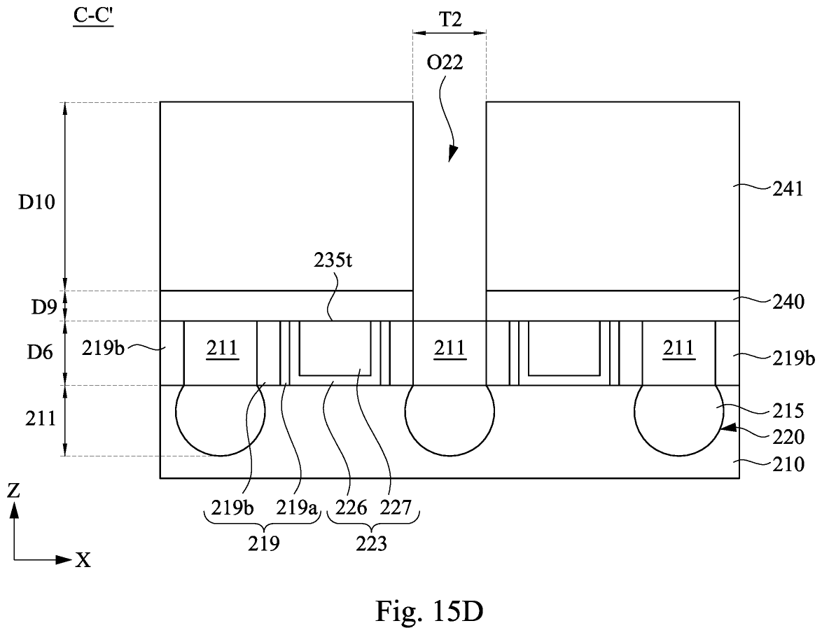

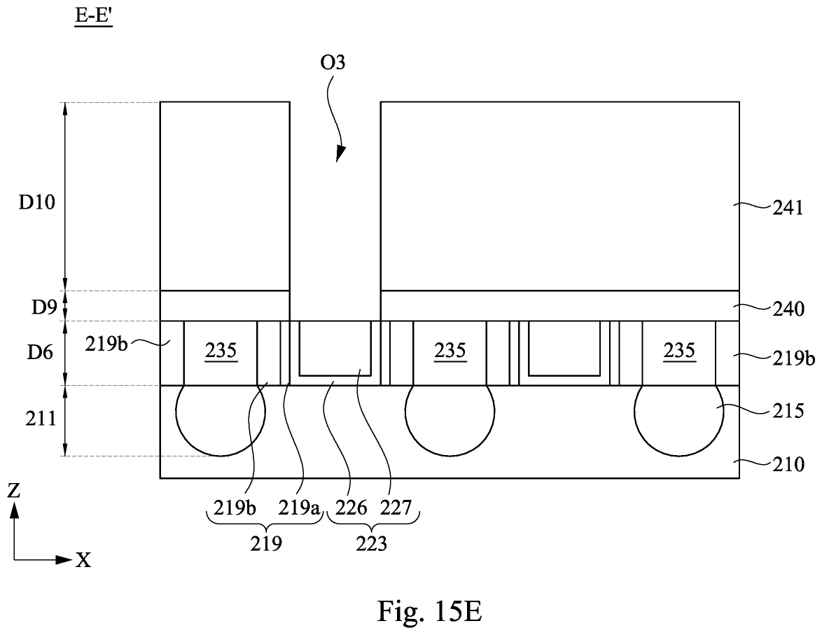

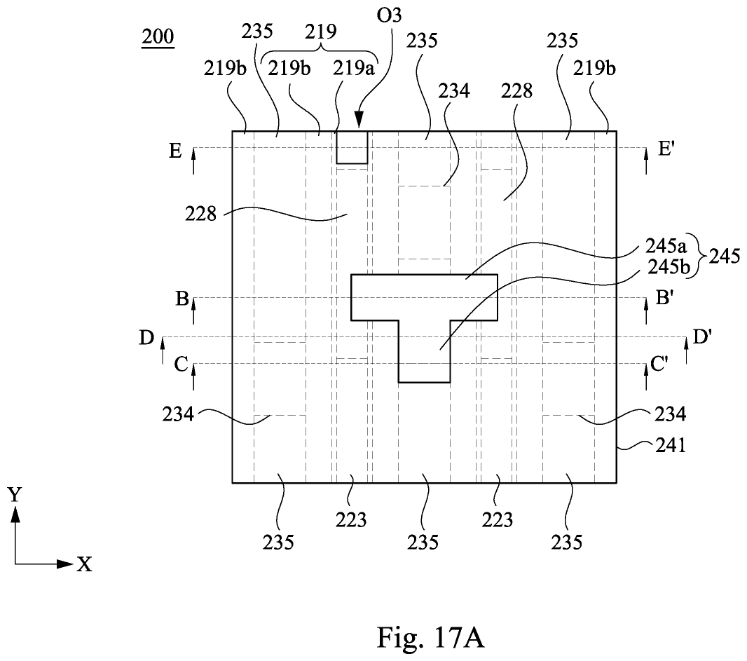

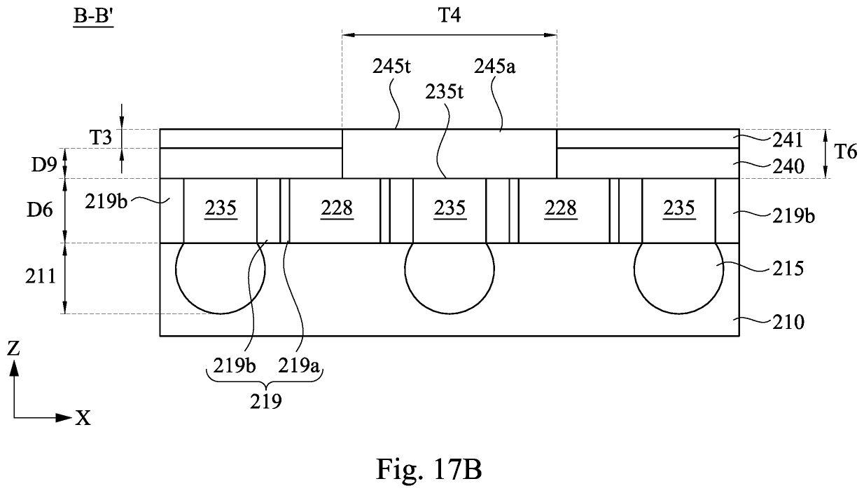

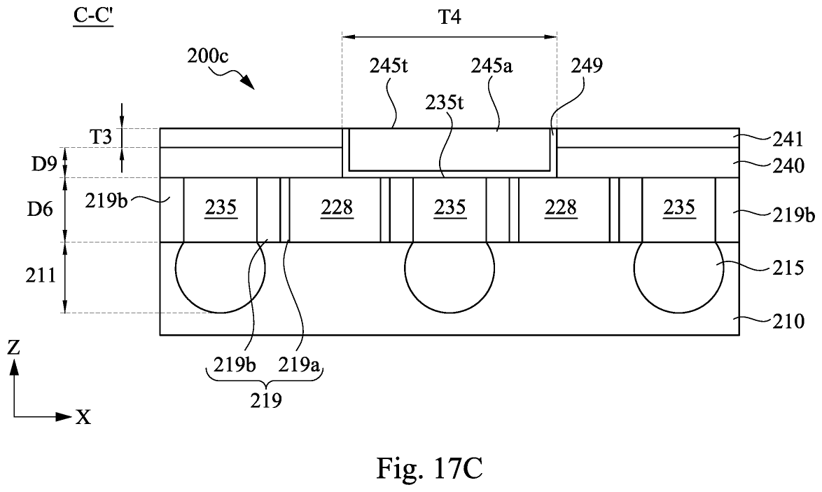

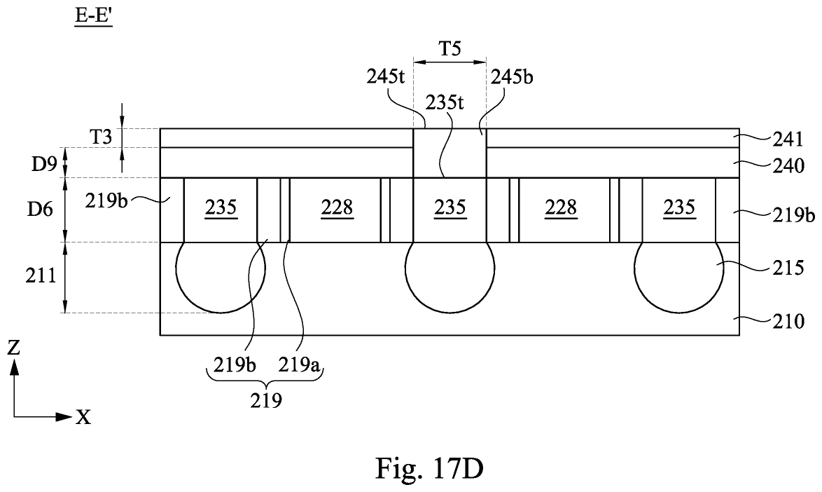

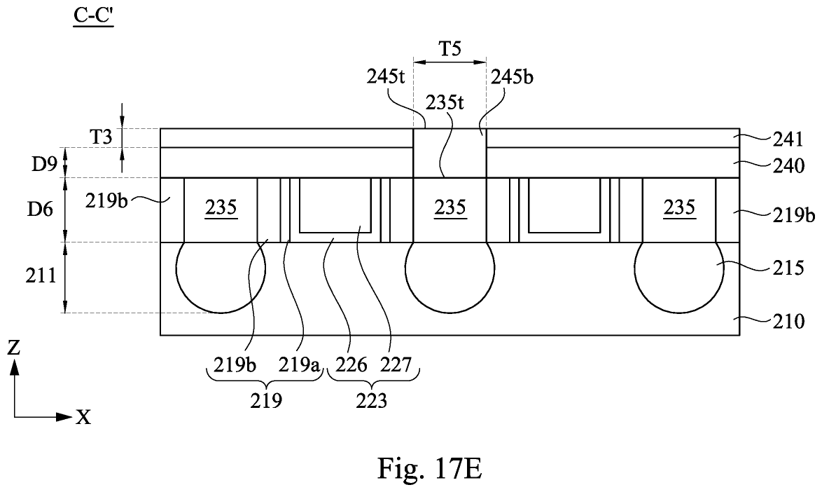

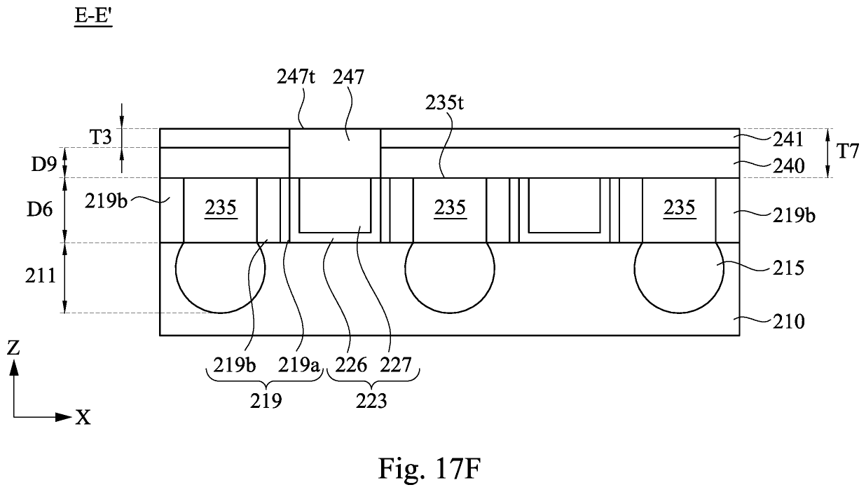

FIGS. 3A, 4A, 5A, 6A, 7A, 8A, 9A, 10A, 11A, 12A, 13A, 14A, 15A, 16A, 17A, and 18A are schematic top views of the semiconductor structure 200 in accordance with some embodiments of the present disclosure. FIGS. 3B, 4B, 5B, 6B, 7B, 8C, 9B, 12B, 13B, 14B, 15B, 16B, 17B, and 18B are cross-sectional views taken along line B-B′ as shown in FIGS. 3A, 4A, 5A, 6A, 7A, 8A, 9A, 10A, 11A, 12A, 13A, 14A, 15A, 16A, 17A, and 18A. FIGS. 10B, 11B, 15D, 16D, 17E, and 18C are cross-sectional views taken along line C-C′ as shown in FIGS. 11A, 15A, 16A, 17A, and 18A. FIGS. 15C, 16C, and 17D are cross-sectional views taken along line D-D′ as shown in FIGS. 15A, 16A, and 17A. FIGS. 15E, 16E, 17F, and 18D are cross-sectional views taken along line E-E′ as shown in FIGS. 15A, 16A, 17A, and 18A. FIG. 8B is a schematic top view a of semiconductor structure 200 corresponding to FIG. 8A according to some embodiments of the present disclosure. FIGS. 7C and 8D are schematic perspective views of semiconductor structures corresponding to FIGS. 7A and 8B, respectively, according to some embodiments of the present disclosure. FIG. 17C is a schematic cross-sectional view of a semiconductor structure corresponding to FIG. 17B according to some embodiments of the present disclosure.

Reference is made to FIGS. 3A and 3B. A substrate 210 is provided for forming transistor Trc (see FIGS. 17A-17F) with a source/drain via having a T-shaped top view profile. The substrate 210 may be a semiconductor substrate, such as a bulk semiconductor, a semiconductor-on-insulator (SOI) substrate, or the like, which may be doped (e.g., with a p-type or an n-type impurity) or undoped. The substrate 210 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 210 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

One or more dielectric isolation structure (e.g., the dielectric isolation structure 112a, 112b, and 112 shown in FIGS. 1A, 1B, and 2A) can be formed in the substrate 210 to define active regions 211 (e.g., the active regions 111, 111a, and 111b shown in FIGS. 1A, 1B, and 2A). Formation of the dielectric isolation structure includes, by way of example and not limitation, etching the substrate 210 to form one or more trenches that define the active region 211, depositing one or more dielectric materials (e.g., silicon oxide) to overfill the trenches in the substrate 210, followed by a CMP process to planarize the one or more dielectric isolation structure with the substrate 210. The dielectric isolation structure can be further recessed (e.g., by an etch back process) to fall below the top surfaces of the active regions 211, such that the active regions 211 protrude above the top surface of the recessed dielectric isolation structure to form fin-like structure. The trenches may be patterned by any acceptable etch process, such as a reactive ion etch (RIE), neutral beam etch (NBE), the like, or a combination thereof. The etching may be anisotropic.

In some embodiments, if the transistor Trc (see FIGS. 17A-17F) formed over the substrate 210 is a FinFET (e.g. transistor Tra shown in FIG. 1A), the fin-like structure can act as a channel region. In some embodiments, if the transistor Trc (see FIGS. 17A-17F) formed over the substrate 210 is a nano-FET (e.g. transistor Trb shown in FIG. 1B), the fin-like structure may include multi-layer stacks. The multi-layer stack may include alternating first semiconductor layers and second semiconductor layers. The first semiconductor layers formed of a first semiconductor material, and the second semiconductor layers are formed of a second semiconductor material. The semiconductor materials may each be selected from the candidate semiconductor materials of the substrate 210. It should be appreciated that the multi-layer stack 42 may include any number of the first semiconductor layers and the second semiconductor layers.

In some embodiments, the first semiconductor layers will be removed and the second semiconductor layers will patterned to form channel regions for the nano-FET. The first semiconductor layers are sacrificial layers (or dummy layers), which will be removed in subsequent processing to expose the top surfaces and the bottom surfaces of the second semiconductor layers, and the second semiconductor layers are patterned to form channel regions for the nano-FET. The first semiconductor material of the first semiconductor layers is a material that has a high etching selectivity from the etching of the second semiconductor layers, such as silicon germanium. The second semiconductor material of the second semiconductor layers is a material suitable for both n-type and p-type devices, such as silicon.

In some embodiments, the first semiconductor material of the first semiconductor layers may be made of a material, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers may be made of a material, such as silicon, silicon carbide, a III-V compound semiconductor, a II-VI compound semiconductor, or the like. The first semiconductor material and the second semiconductor material may have a high etching selectivity from the etching of one another. Each of the layers of the multi-layer stack may be grown by a process such as vapor phase epitaxy (VPE) or molecular beam epitaxy (MBE), deposited by a process such as chemical vapor deposition (CVD) or atomic layer deposition (ALD), or the like.

Sacrificial gate structures 213 are formed over the active region 211. The sacrificial gate structures 213 may include a sacrificial gate dielectric layer and a sacrificial gate over the sacrificial gate dielectric layer. In some embodiments, by way of example and not limitation, a sacrificial gate dielectric material (e.g., silicon oxide, silicon nitride, or the like) may be deposited over the substrate 210, a sacrificial gate material (e.g., doped or un-doped polysilicon) may be deposited over the dummy gate dielectric material and then planarized (e.g., by CMP), and the sacrificial gate material and sacrificial gate dielectric material are then patterned by using suitable photolithography and etching techniques, resulting in sacrificial gate structures 213 each including sacrificial gate dielectric material and sacrificial gate material to serve as its corresponding sacrificial gate dielectric layer and sacrificial gate. In some embodiments, the sacrificial gate structures 213 can be interchangeably referred to dummy gate structures. In some embodiments, the sacrificial gate structure 213 can have a vertical dimension D1 (or height) in a range from about 0-50 nm, such as about 5, 10, 15, 20, 25, 30, 35, 40, 45, or 50 nm.

Gate spacers 219 are then formed on opposite sidewalls of each sacrificial gate structure 213. The gate spacer 219 can include a spacer layer 219a and a spacer layer 219b over the spacer layer 219a and having a different material than the spacer layer 219a. In some embodiments, the gate spacers 219 are formed by, for example, deposition and anisotropic etch of at least one spacer dielectric layer performed after the sacrificial gate patterning is complete. In some embodiments, the spacer dielectric layers may include one or more dielectrics, such as silicon oxide, silicon nitride, silicon oxynitride, silicon carbide, silicon carbonitride, the like, or a combination thereof. The spacer dielectric layers may be deposited by a conformal deposition process, such as ALD, CVD, or the like. The anisotropic etch process removes the spacer dielectric layer from over the top of the sacrificial gate structures 213 while leaving the gate spacers 219 along the sidewalls of the sacrificial gate structures 213.

In some embodiments, if the transistor Trc (see FIGS. 17A-17F) formed over the substrate 210 is a nano-FET (e.g. transistor Trb shown in FIG. 1B), inner spacers may be further formed on sidewalls of the first semiconductor sheets, and the first semiconductor sheets will be subsequently replaced with corresponding gate structures. The inner spacers act as isolation features between the subsequently formed source/drain regions and the subsequently formed gate structures. Further, the inner spacers may be used to substantially prevent damage to the subsequently formed source/drain regions by subsequent etching processes, such as etching processes used to subsequently remove the first semiconductor sheets. In some embodiments, the inner spacers can be interchangeably referred to lower gate spacers.

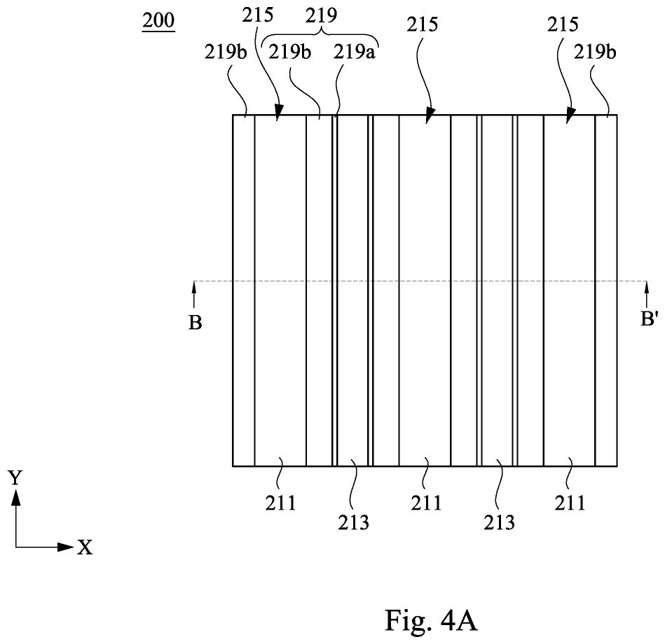

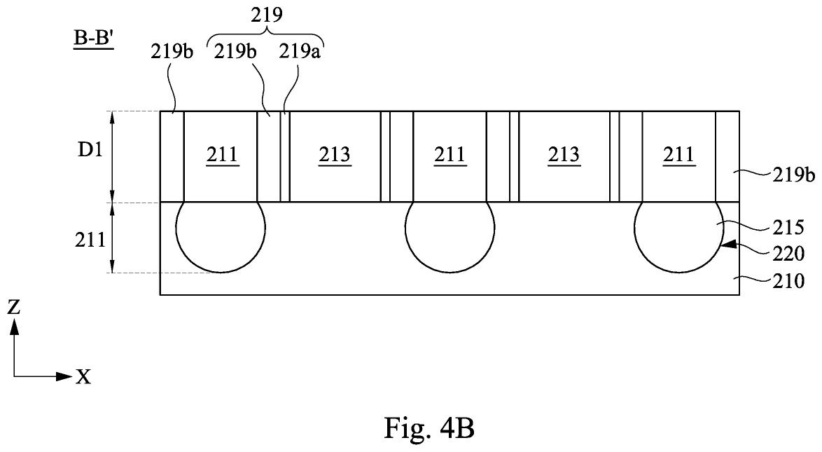

Reference is made to FIGS. 4A and 4B. Source/drain regions 215 are formed in the active region 211 and self-aligned to the gate spacers 219. Specifically, source/drain recesses 220 (see FIG. 4B) are formed in the active region 211. The source/drain recesses 220 may be formed by etching the active region 211 using an anisotropic etching process, such as a RIE, a NBE, or the like. The gate spacers 219 and the sacrificial gate structures 213 collectively mask portions of the active region 211 during the etching processes used to form the source/drain recesses 220. A single etch process may be used to etch the active region 211, or multiple etch processes may be used to etch the active region 211. Timed etch processes may be used to stop the etching of the source/drain recesses 220 after the source/drain recesses 220 reach a desired depth.

The source/drain regions 215 can be formed in the source/drain recesses 220. A portion of the active region 211 (i.e., fin-like structure) between the corresponding source/drain regions 215 can serve as the channel regions 214. In some embodiments, the source/drain regions 215 may include Ge, Si, GaAs, AlGaAs, SiGe, GaAsP, SiP, or other suitable material. The source/drain regions 215 may be in-situ doped during the epitaxial process by introducing doping species including: p-type dopants, such as boron or BF₂; n-type dopants, such as phosphorus or arsenic; and/or other suitable dopants including combinations thereof. If the source/drain regions 215 are not in-situ doped, an implantation process (i.e., a junction implant process) is performed to dope the source/drain regions 215. In some exemplary embodiments, the source/drain regions 215 in an n-type include Si: P. In some embodiments, the source/drain regions 215 can be interchangeably referred to as source/drain regions, source/drain patterns, or source/drain structures.

Subsequently, an interlayer dielectric (ILD) layer 221 can be formed over the source/drain regions 215 and the sacrificial gate structures 213 by depositing a dielectric material over the substrate 210, and then planarizing the dielectric material (e.g., by using CMP) until the sacrificial gate structures 213 are exposed. The ILD layer 221 may be deposited by any suitable method, such as CVD, plasma-enhanced CVD (PECVD), FCVD, or the like. Acceptable dielectric materials may be included in the ILD layer 221, such as phospho-silicate glass (PSG), boro-silicate glass (BSG), boron-doped phospho-silicate glass (BPSG), undoped silicate glass (USG), or the like. Other insulation materials formed by any acceptable process may be used for the ILD layer 221.

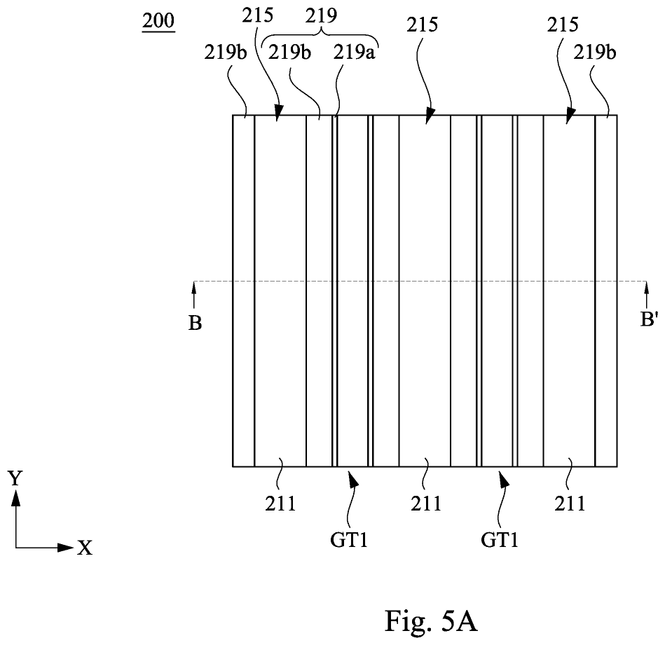

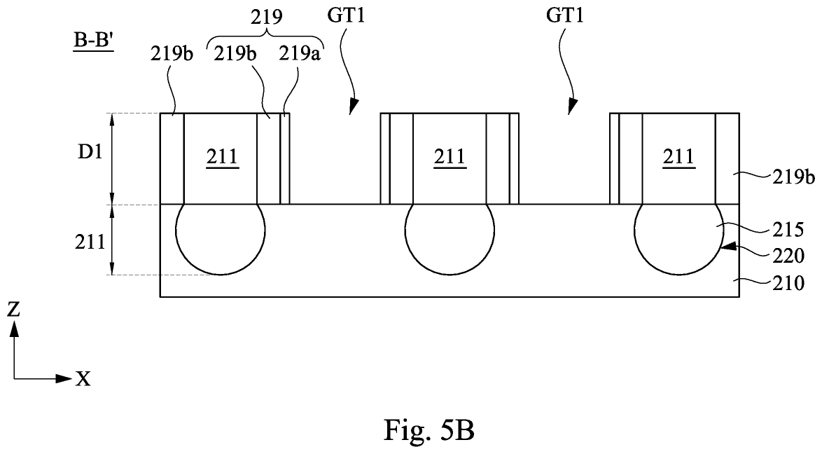

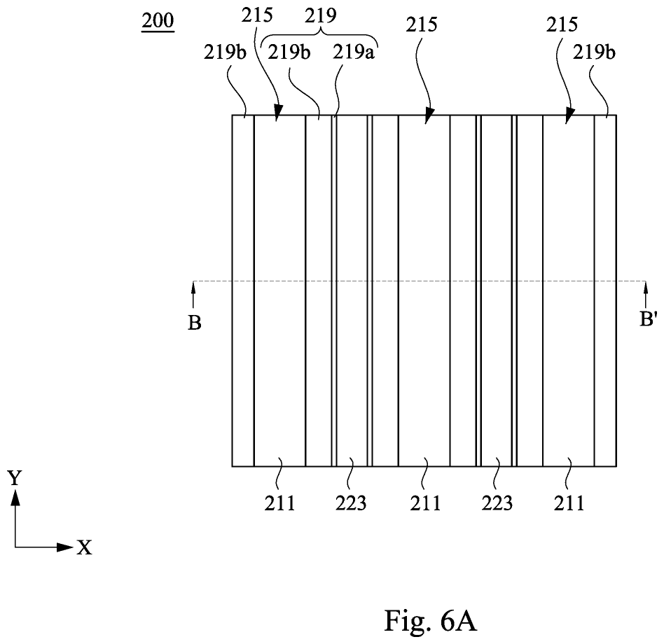

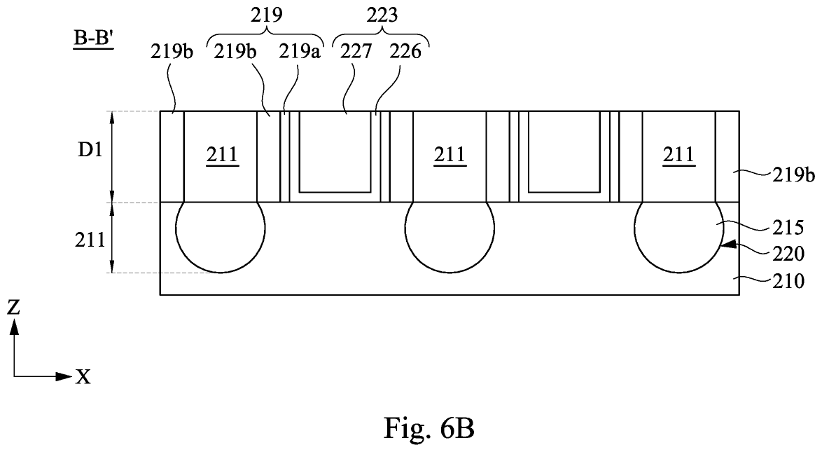

Reference is made to FIGS. 5A-6B. The sacrificial gate structures 213 are replaced with gate structures 223. Fabrication of the source/drain regions 221 and the gate structures 223 of transistors Trc can be referred to as a front-end-of-line (FEOL) processing. As shown in FIGS. 5A and 5B. The gate replacement process includes, by way of example and not limitation, removing the sacrificial gate structures 213 using one or more etching techniques, thereby creating gate trenches GT1 between respective gate spacers 219. In some embodiments, the sacrificial gate structures 213 can be removed by an anisotropic dry etch process. For example, the etching process may include a dry etch process using reaction gas(es) that selectively etch the sacrificial gate structures 213 at a faster rate than the ILD layer 221 and the gate spacers 219.

Subsequently, as shown in FIGS. 6A and 6B, a gate dielectric layer 226 comprising one or more dielectrics, followed by a gate electrode layer 227 comprising one or more metals, are deposited to completely fill the gate trenches GT1. Excess portions of the gate dielectric layer 226 and the gate electrode layer 227 are then removed from over the top surface of the ILD layer 221 using, for example, a CMP process. In some embodiments, the resulting structure, as illustrated in FIGS. 6A and 6B, may include remaining portions of the gate dielectric layer 226 and the gate electrode layer 227 inlaid between respective gate spacers 219 to serve as the gate structures 223.

In some embodiments, the gate dielectric layer 226 may be made of a high-k dielectric material. In some embodiments, the high-k gate dielectric materials include, but are not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), metal oxides, metal nitrides, metal silicates, transition metal-oxides, transition metal-nitrides, transition metal-silicates, oxynitrides of metals, metal aluminates, zirconium silicate, zirconium aluminate, zirconium oxide, titanium oxide, aluminum oxide, hafnium dioxide-alumina (HfO₂—Al₂O₃) alloy, other suitable high-k dielectric materials, and/or combinations thereof. The gate metal(s) is formed over the gate dielectric. Exemplary gate metal layer(s) 227 can be a single layer structure or a multi-layer structure including, for example, copper (Cu), aluminum (Al), titanium (Ti), titanium nitride (TiN), tantalum (Ta), tantalum nitride (TaN), tantalum carbide (TaC), tantalum silicon nitride (TaSiN), tungsten (W), tungsten nitride (WN), molybdenum nitride (MoN), the like and/or combinations thereof. In some embodiments, the materials used in forming the gate structures 223 may be deposited by any suitable method, e.g., CVD, PECVD, PVD, ALD, PEALD, electrochemical plating (ECP), electroless plating and/or the like.

In some embodiments, if the transistor Trc (see FIGS. 17A-17F) formed over the substrate 210 is a nano-FET (e.g. transistor Trb shown in FIG. 1B), the first semiconductor sheets can be exposed from the gate trench GT1 and then removed to form openings in regions between the second semiconductor sheets. The first semiconductor sheets can be removed by any acceptable etching process that selectively etches the material of the first semiconductor sheets at a faster rate than the material of the second semiconductor sheets. The etching may be isotropic. For example, when the first semiconductor sheets are formed of silicon germanium and the second semiconductor sheets are formed of silicon, the etching process may be a wet etch using tetramethylammonium hydroxide (TMAH), ammonium hydroxide (NH₄OH), or the like. In some embodiments, the removing of the first semiconductor sheets can be interchangeably referred to as a channel releasing process. The second semiconductor sheets can be interchangeably referred to as a vertically stacked multiple channels (sheets). Subsequently, the gate dielectric layer 226 and the gate electrode layer 227 can be further formed in the regions between the second semiconductor sheets to wrap around the second semiconductor sheets.

Reference is made to FIGS. 7A-8C. The dielectric regions 228 (see FIG. 8B) are formed in of the gate structures 223. In some embodiments, each dielectric region 228 is a gate-cut structure for the gate structure 223, and the gate-cut structure is formed by a cut metal gate (CMG) process. In some embodiments, the dielectric region 228 can be interchangeably referred to a gate end dielectric. Specifically, as shown in FIGS. 7A and 7B, a portion of the gate electrode layer 227 (and gate dielectric layer 226) can be removed to form a gate trench GT2, and the cut metal gate process may be further performed to decrease the thicknesses of the sacrificial gate structures 213 to a vertical dimension D2 (or height). In some embodiments, the vertical dimension D2 can be less than the dimension D1 (see FIG. 3B). By way of example and not limitation, the vertical dimension D2 can be in a range from about 0-50 nm, such as about 5, 10, 15, 17, 20, 25, 30, 35, 40, 45, or 50 nm. The portion of the gate electrode layer 227 may be removed by dry etching, wet etching, or a combination of dry and wet etching. For example, a wet etching process may include exposure to a hydroxide containing solution (e.g., ammonium hydroxide), deionized water, and/or other suitable etchant solutions.

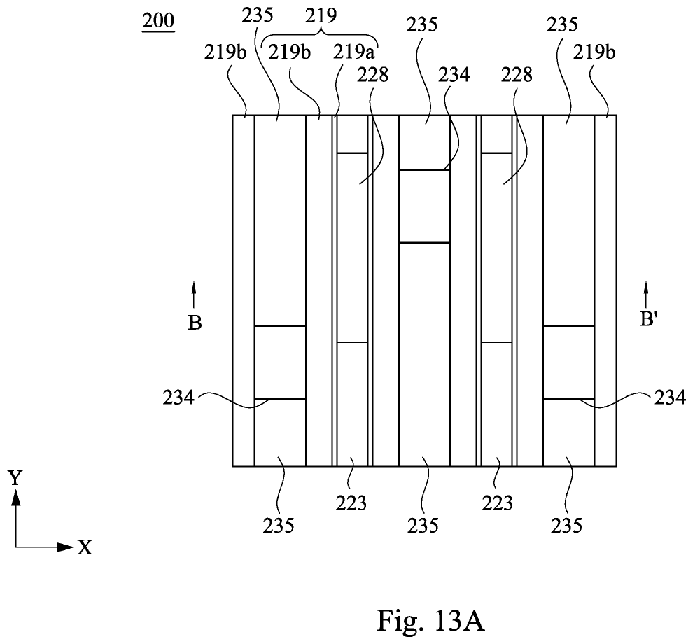

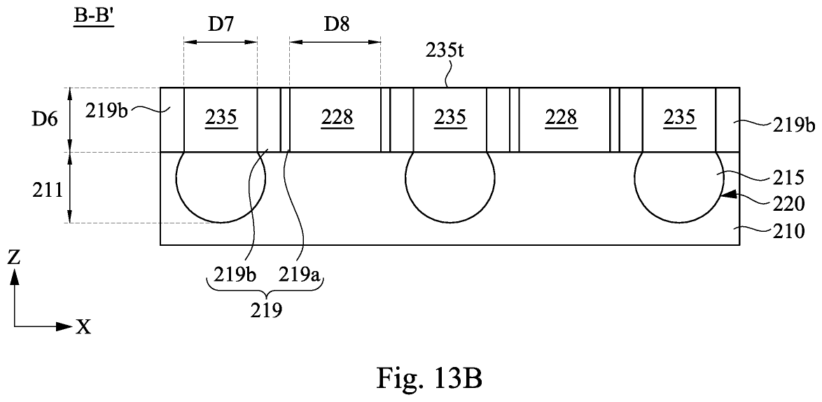

Subsequently, as shown in FIGS. 8A-8C, a dielectric material 228′ is deposited into the gate trenches GT2 and over the ILD layer 221. The dielectric material 228′ forms the dielectric regions 228 (see FIG. 13B) in the gate trenche GT2. In some embodiments, a planarization process can be further performed to remove excess portions of the dielectric material 228′ over the ILD layer 221. In some embodiments, the deposition of the dielectric material 228′ of the dielectric region 228 can be performed using a deposition process such as ALD, which may be PEALD, thermal ALD, or the like. The dielectric material 228′ may be formed of or comprise SiO₂, SiOC, SiOCN, or the like, or combinations thereof. In some embodiments, the dielectric region 228 may be made of a nitride-based material, such as Si₃N₄, or a carbon-based material, such as SiOCN, or combinations thereof. In some embodiments, the dielectric region 228 may be made of a material having a dielectric constant greater than about 9 (e.g., high dielectric constant (high-k) material). For example, the dielectric region 228 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The dielectric region 228 may be formed of a homogenous material, or may have a composite structure including more than one layer.

Reference is made to FIGS. 7C and 8D. FIG. 7C is a schematic perspective view of a semiconductor structure 200a corresponding to FIGS. 7A and 7B according to some embodiments of the present disclosure. FIG. 8D is a schematic perspective view of a semiconductor structure 200b corresponding to FIGS. 8A-8C according to some embodiments of the present disclosure. While FIGS. 7C and 8D show an embodiment of semiconductor structures 200a and 200b with different layouts than the semiconductor structure 200 in FIGS. 3A-7C, 8A-8C, and 9A-18D. In addition, the present disclosure may repeat reference numerals and/or letters in the various examples. This repetition is for the purpose of simplicity and clarity and does not in itself dictate a relationship between the various embodiments and/or configurations discussed.

As shown in FIG. 7C, the dielectric isolation structure 212, such as a shallow trench isolation (STI) structure, formed over the substrate 210. The dielectric isolation structure 212 can define and electrically isolate the active region 111 of the transistor. the gate structures 223 on the boundary of the circuit regions are replaced with dielectric-base gates 260 to form isolation regions separating the source/drain regions of neighboring semiconductor devices from each other and separate different semiconductor devices. The isolation region may be formed by using an etching process. In the etching process, the etching may be stopped on the dielectric isolation structure 212. In some embodiments, the gate structures 223 on the boundary of the logic circuit region can be etched anisotropically into the substrate 210 (see FIG. 8D). Subsequently, a dielectric material is filled in the isolation region (i.e., spaces originally occupied by the gate structures 223) to form dielectric-base gates 260. In some embodiments, the dielectric-base gate 260 can be interchangeably referred to as dummy gate. The gate structure 223 can be arranged between the dielectric-base gates 260. In some embodiments, the dielectric-base gates 260 can be made of silicon oxide (SiOₓ), silicon nitride (SiₓN_{y}), silicon oxynitride (SiON), dielectric material(s), other suitable material, or a combination thereof. In some embodiments, the dielectric-base gates 260 can be formed by a deposition process, such as chemical vapor deposition (CVD), physical vapor deposition (PVD), atomic layer deposition (ALD), high density plasma CVD (HDPCVD), metal organic CVD (MOCVD), or plasma enhanced CVD (PECVD).

As shown in FIG. 7C, a patterned hard mask 262 covers the gate structure 223, but a portion of the gate structure 223 is exposed by trenches 263 formed on the patterned hard mask 262. In some embodiments, the exposed portion of the gate structure 223 conforms to the cut regions of the dielectric region 228b (see FIG. 8D). In some embodiments, the trenches 263 are extending along the lengthwise direction of the channel region 214 above fin 218b protruding from the substrate 210. The trenches 263 may extend across the gate structure 223 and the dielectric-base gates 260.

As shown in FIG. 8D, portions of the gate structures 223 (and the gate spacers 219, the dielectric-base gates 260) can be removed from the trenches 263 (see FIG. 7C) to form a gate trench GT3 in the gate structures 223. The portions of the gate structures 223 (and the gate spacers 219, the dielectric-base gates 260) may be removed by dry etching, wet etching, or a combination of dry and wet etching. For example, a wet etching process may include exposure to a hydroxide containing solution (e.g., ammonium hydroxide), deionized water, and/or other suitable etchant solutions. A dielectric material is deposited into the gate trenches GT3 and over the ILD layer 221. The dielectric material forms the dielectric regions 228b in the gate trench GT3. In some embodiments, a planarization process can be further performed to remove excess portions of the dielectric material over the ILD layer 221. In some embodiments, material and manufacturing method of the dielectric regions 228b may be substantially the same as that of the dielectric regions 228, and the related detailed descriptions may refer to the foregoing paragraphs, and are not described again herein. In some embodiments, the dielectric region 228b form to extend across the gate structure 223 and the dielectric-base gates 260 and have a straight seam 228c therein.

As shown in FIG. 8D, the source/drain regions 215 on opposite sides of the channel region 214 and connected to the channel region 214, and the gate structure 223 wrapping around the channel region 214. In some embodiments, inner spacers 236 can be formed between the source/drain regions 215 and the corresponding gate structures 223 and serve to isolate the gate structures 223 from source/drain regions 215. The inner spacer 236 may be a low-k dielectric material, such as SiO₂, silicon nitride (SiN), silicon carbonoxide (SiCO), silicon carbonnitride (SiCN), silicon oxycarbonnitride (SiOCN). The inner spacer 236b can be formed using CVD, including LPCVD and PECVD, PVD, ALD, or other suitable processes.

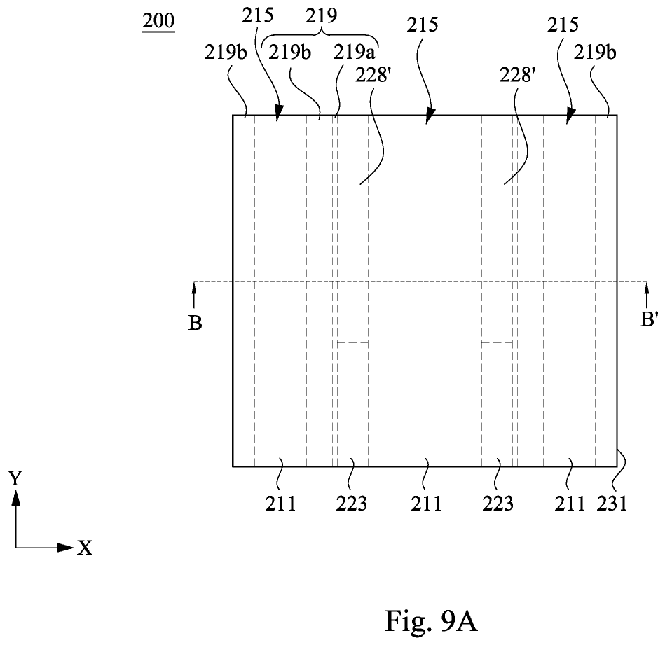

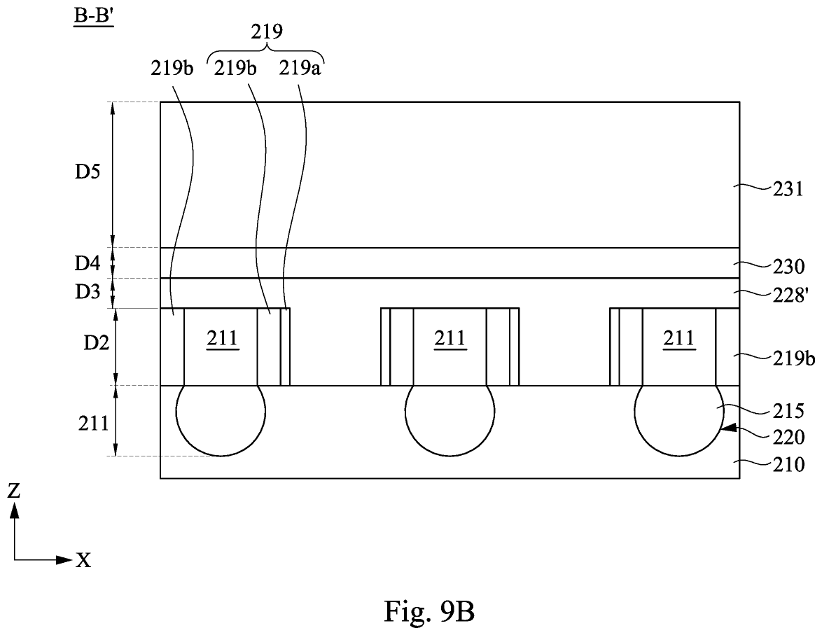

Reference is made to FIGS. 9A and 9B. A contact etch stop layer (CESL) 230 and an ILD layer 231 can be formed over the gate structure 223 and the ILD layer 221. As shown in FIGS. 9A and 9B, the CESL 230 is deposited over the gate structure 223 and the ILD layer 221. Subsequently, the ILD layer 231 is deposited over the CESL 230. In some embodiments, a portion of the dielectric material 228′ over the ILD layer 221 can have a vertical dimension D3 (or thickness) in a range from about 0-20 nm, such as about 2, 3, 4, 6, 8, 10, 12, 14, 16, 18, or 20 nm. The CESL 230 can have a vertical dimension D4 (or thickness) in a range from about 0-20 nm, such as about 2, 3, 4, 6, 8, 10, 12, 14, 16, 18, or 20 nm. The ILD layer 231 can have a vertical dimension D5 (or thickness) in a range from about 0.1-50 nm, such as about 0.1, 1, 5, 10, 15, 20, 25, 30, 35, 40, 45, or 50 nm. In some embodiments, the vertical dimension D5 is greater than the vertical dimension D4. In some embodiments, the vertical dimension D4 can be substantially the same as the vertical dimension D3. In some embodiments, the vertical dimension D4 may be greater than or less than the vertical dimension D3.

By way of example and not limitation, the CESL 230 may be formed of a dielectric material, such as silicon nitride, silicon oxide, silicon oxynitride, or the like, having a high etching selectivity from the etching of the ILD layer 231. The CESL 230 may be formed by any suitable method, such as CVD, ALD, or the like. Subsequently, the ILD layer 231 is deposited over the CESL 230. The ILD layer 231 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

Reference is made to FIGS. 10A-11B. The dielectric regions 234 (see FIG. 15D) are formed over the source/drain regions 215 to separate the source/drain contacts 235 (see FIGS. 13A and 13B) on the source/drain regions 215. In some embodiments, each dielectric region 234 is a metal-like defined region (MD)-cut structure for forming the source/drain contact 235, and the MD-cut structure is formed by a cut metal-like defined region (CMD) process. In some embodiments, the ILD layer 221 over the source/drain regions 215 can be patterned to form the dielectric region 234.

Specifically, as shown in FIGS. 10A and 10B, hard mask layers 237 are formed over the ILD layer 221 overlaying the source/drain regions 215. The hard mask layer 237 can act as etch mask during the etching process to form the dielectric region 234. In some embodiments, the hard mask layer 237 may be made of dielectric material, such as SiO₂, Si₃N₄, SiON, SiOC, SiOCN base dielectric material, or combinations thereof.

Subsequently, as shown in FIGS. 11A and 11B, the ILD layer 231, the CESL 230, and the ILD layer 221 are patterned by using suitable photolithography and etching techniques to form openings O1 that expose the source/drain regions 215, resulting in dielectric regions 234 (see FIG. 15D) each including a remainder of the ILD layer 221 to serve as its corresponding dielectric region 234. In some embodiments, the ILD layer 231, the CESL 230, and the ILD layer 221 can be etched by an anisotropic dry etch process. For example, the etching process may include a dry etch process using reaction gas(es) that selectively etch the ILD layer 231, the CESL 230, and the ILD layer 221 at a faster rate than the ILD layer 221 and the hard mask layer 237.

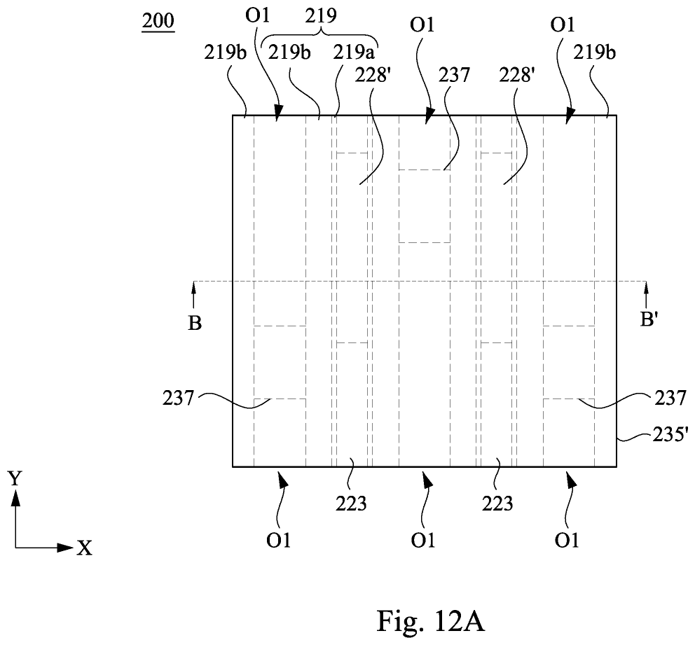

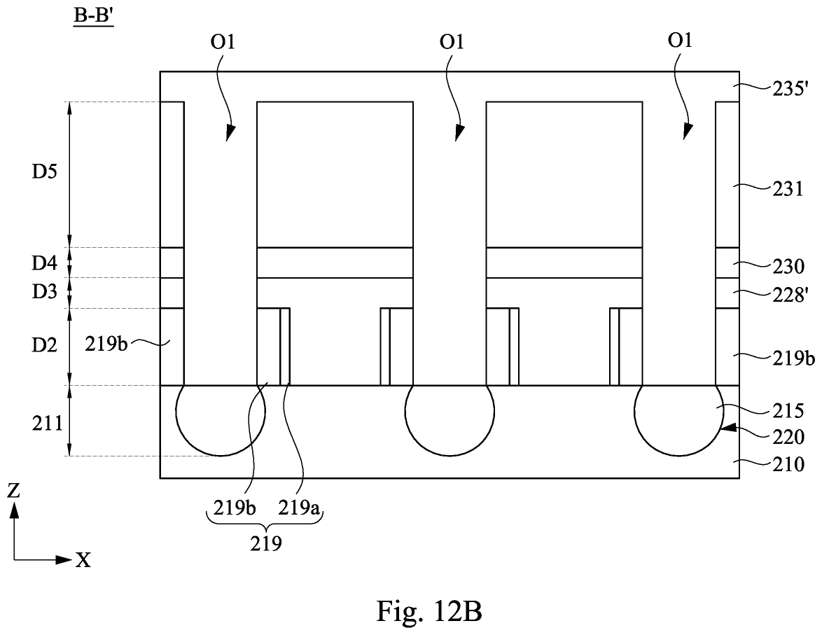

Reference is made to FIGS. 12A-13B. The source/drain contacts 235 (see FIGS. 12A and 12B) can be formed over the source/drain regions 215 and spaced apart from an adjacent one thereof by the dielectric region 234. As shown in FIGS. 12A and 12B, a contact material 235′ is deposited over the ILD layer 231 and in the openings O1. The contact material 235′ may be deposited by chemical vapor deposition (CVD), physical vapor deposition (PVD), sputter deposition, or other techniques suitable for depositing conductive materials. The contact material 235′ may include a metal-containing material such as titanium nitride, titanium oxide, tungsten, cobalt, ruthenium, aluminum, copper, combinations thereof, multi-layers thereof, or the like.

Subsequently, as shown in FIGS. 13A and 13B, a planarization process such as a chemical mechanical polish (CMP), an etch-back process, combinations thereof, or the like may be utilized to remove the ILD layer 231, the CESL 230, and an excess portion of the dielectric region 234 over the top surface of the ILD layer 221. In some embodiments, the planarization process may (not separately illustrated) be further performed to decrease the thicknesses of the contact material 235′, the gate structures 223, the dielectric material 228′ (see FIG. 12B), the dielectric region 234, and the surrounding element thereof to a vertical dimension D6 (or thickness), resulting in source/drain contacts 235 each including remainders of the contact material 235′ and the dielectric region 228 each including remainders of the dielectric material 228′. The source/drain contact 235 can have a top surface 235t coplanar with a top surface 223t (see FIG. 15D) of the gate structures 223. In other words, the top surface 235t of the source/drain contact 235 can be level with the top surface 223t of the gate structure 223.

In some embodiments, the vertical dimension D6 can be less than the dimension D2 (see FIG. 7B). By way of example and not limitation, the vertical dimension D2 can be in a range from about 0-50 nm, such as about 5, 10, 12, 15, 20, 25, 30, 35, 40, 45, or 50 nm. In some embodiments, the source/drain contact 235 can have a lateral dimension D7 (or width) along the lengthwise direction of the channel region 214 in a range from about 0-50 nm, such as about 0.1, 5, 10, 12, 15, 20, 25, 30, 35, 40, 45, or 50 nm. In some embodiments, the dielectric region 228 can have a lateral dimension D8 (or width) along the lengthwise direction of the channel region 214 in a range from about 0-50 nm, such as about 0.1, 5, 10, 12, 15, 20, 25, 30, 35, 40, 45, or 50 nm. The lateral dimension D7 can be substantially the same as the lateral dimension D8. In some embodiments, the lateral dimension D7 may be greater than or less than the lateral dimension D8. In some embodiments, the source/drain contacts 235 can be interchangeably referred to as a metal-like defined region (MD) structure.

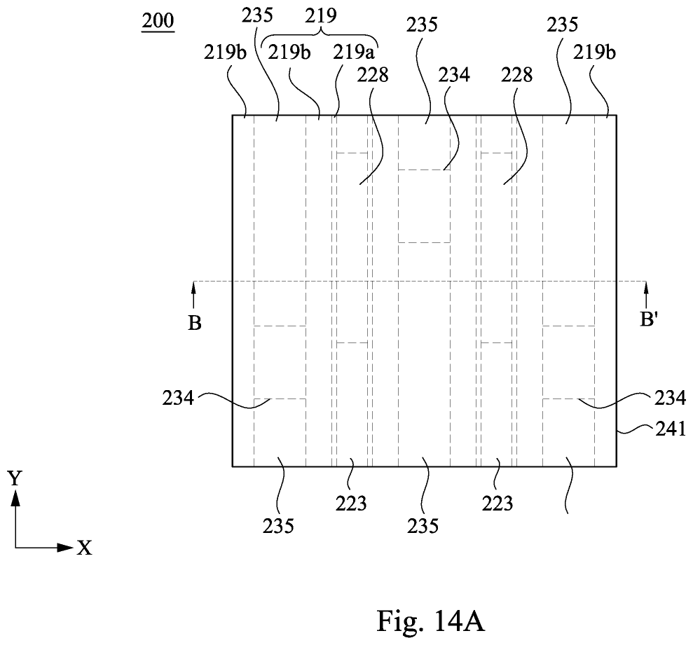

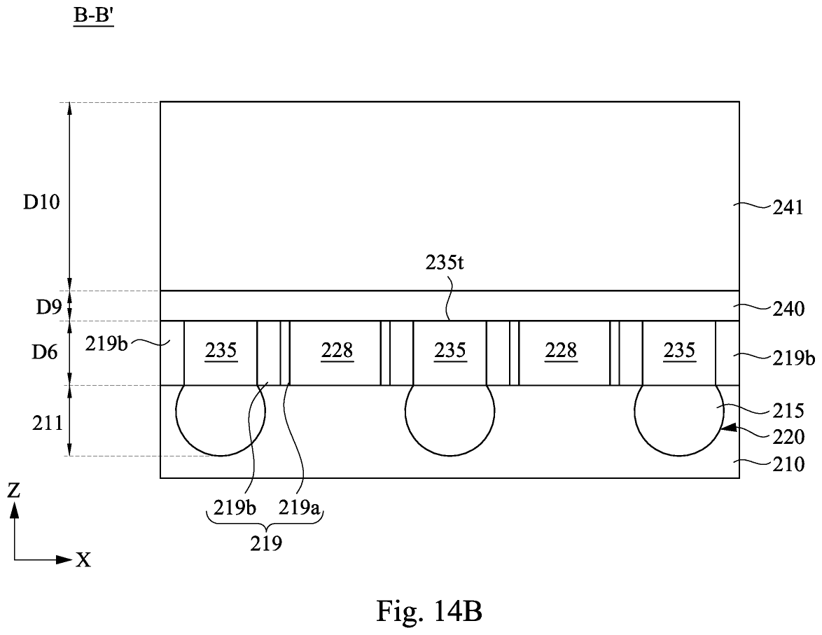

Reference is made to FIGS. 14A and 14B. A contact etch stop layer (CESL) 240 and an ILD layer 241 can be formed over the structure shown in FIGS. 13A and 13B. As shown in FIGS. 14A and 14B, the CESL 240 is deposited over the gate structure 223, the source/drain contacts 235, the ILD layer 221, and the dielectric regions 234 and 228. Subsequently, the ILD layer 240 is deposited over the CESL 240. In some embodiments, the CESL 240 can have a vertical dimension D9 (or thickness) in a range from about 0-30 nm, such as about 5, 10, 15, 20, 25, or 30 nm. The ILD layer 241 can have a vertical dimension D10 (or thickness) in a range from about 0.1-80 nm, such as about 0.1, 5, 10, 15, 20, 25, 30, 35, 40, 45, 50, 55, 60, 65, 70, 75, or 80 nm. In some embodiments, the vertical dimension D10 is greater than the vertical dimension D9.

The CESL 240 may be formed of a dielectric material, such as silicon nitride, silicon oxide, silicon oxynitride, or the like, having a high etching selectivity from the etching of the ILD layer 241. The CESL 240 may be formed by any suitable method, such as CVD, ALD, or the like. Subsequently, the ILD layer 241 is deposited over the CESL 240. The ILD layer 241 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

Reference is made to FIGS. 15A-17B and 17D-17F. A source/drain via 245 (see FIGS. 17A and 17B) and a gate via 247 (see FIGS. 17A and 17C) are formed over the source/drain contact 235 and the gate structure 213. The semiconductor structure 200 can provide the source/drain via 245 (see FIGS. 17A-17E) with a T-shaped top view profile (see FIG. 17A), so as to expand the volume of source/drain via 245. By increasing the volume of the source/drain via 245, the increased volume can be available for current to flow increases. Given that the resistance is inversely proportional to the volume, a larger source/drain via 245 will reduce the contact resistance, such that Rc of source/drain via 245 can be reduced by such as at least about 50%. In some embodiments, by enlarging the volume of the source/drain via 245, the distance between the gate structure 223 and the source/drain contact 235 can be further modified. Capacitance is directly proportional to the surface area of the plates and inversely proportional to the distance between them. Due to the increased volume of the source/drain via 245, the modification can reduce the overlap area and distance between the gate structure 223 and the source/drain contact 235, leading to a reduced effective capacitance (Ceff), such as at least about 3% Ceff reduction in FEOL.

To enlarge the volume of the source/drain via 245, the semiconductor structure 200 can provide a T-shaped top view profile for the source/drain via 245. This T-shaped top view profile can maximize the area available for current flow and to optimize the device's electrical properties. One of the steps to achieve the T-shaped view profile for the source/drain via 245 can involve enlarging the critical dimension of the dielectric region 228. By expanding this dimension, more space is made available for the source/drain via 245 to adopt its T-shaped view profile.

As shown in FIGS. 15A-15E. The ILD layer 241 (and CESL 240) is patterned using acceptable photolithography and etching techniques to form openings O2 and O3. The pattern of the opening O2 is then transferred to the CESL 240 by any acceptable etching technique to at least expose the source/drain contact 235, and the pattern of the opening O3 is then transferred to the CESL 240 by any acceptable etching technique to at least expose the gate structure 213. In some embodiments, the opening O2 can have a T-shaped top view profile (see FIG. 15A) and have a first portion O21 (see FIGS. 15A and 15B) extending in the lengthwise direction of the channel region 214 and a second portion O22 (see FIGS. 15A and 15C) extending in the lengthwise direction of the gate structures 223. As shown in FIG. 15B, the first portion O21 of the opening O2 can expose the source/drain contact 235 and the dielectric regions 228 on opposite sides of the source/drain contact 235. In some embodiments, the first portion O21 of the opening O2 may have a lateral dimension T1 (or width) in a range from about 0.1 to 100 nm, such as 0.1, 10, 20, 30, 40, 50, 60, 70, 80, 90, or 100 nm.

As shown in FIGS. 15C and 15D, the second portion O22 of the opening O2 can expose the source/drain contact 235 and have a lateral dimension T2 (or width). The lateral dimension T2 may be substantially the same as the lateral dimension D7 (see FIG. 7B) of the source/drain contact 235. In some embodiments, the lateral dimension T2 of the second portion O22 of the opening O2 can be greater than or less than the lateral dimension D7 of the source/drain contact 235. In some embodiments, the lateral dimension T1 of the first portion O21 is greater than the lateral dimension T2 of the second portion O22.

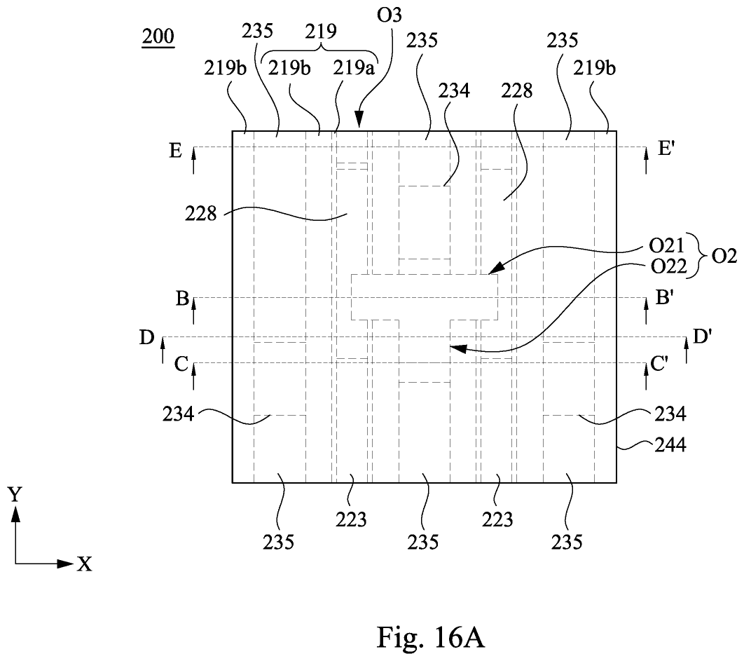

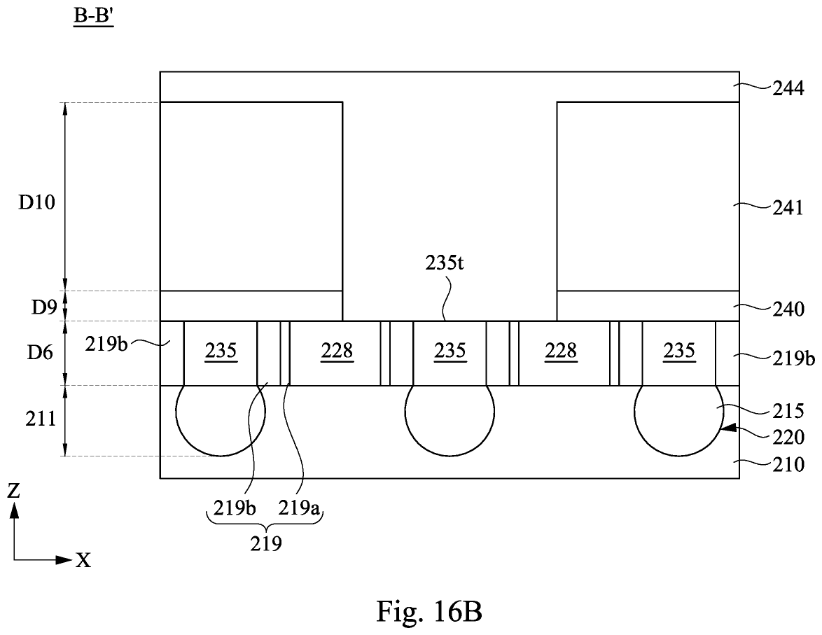

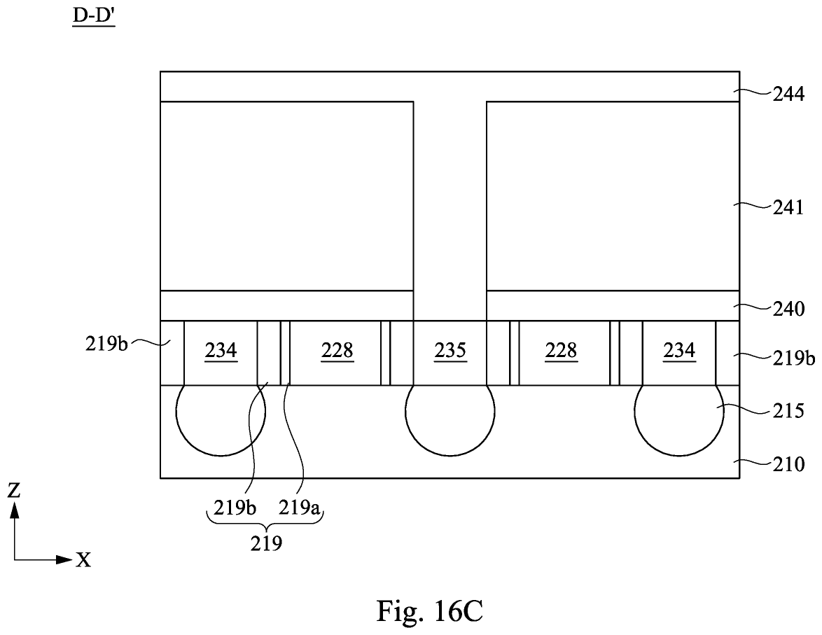

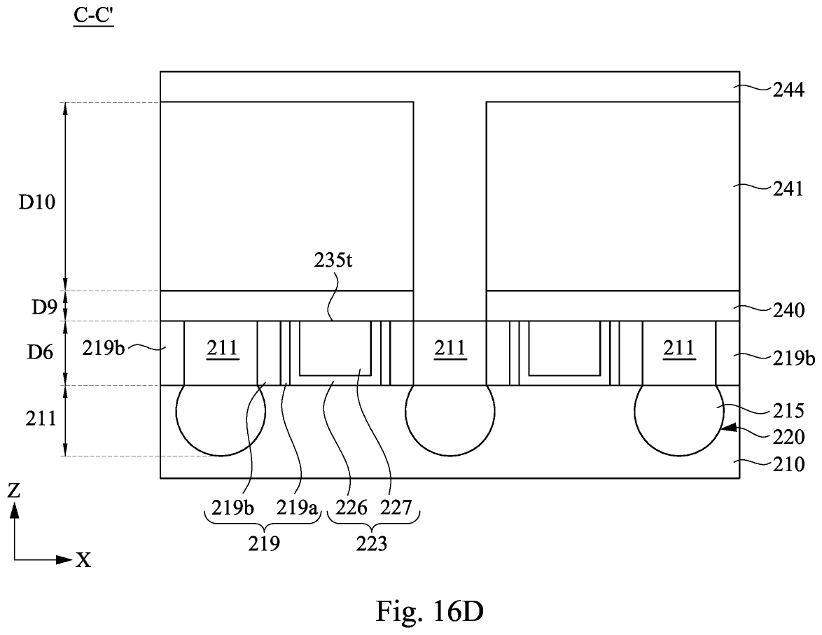

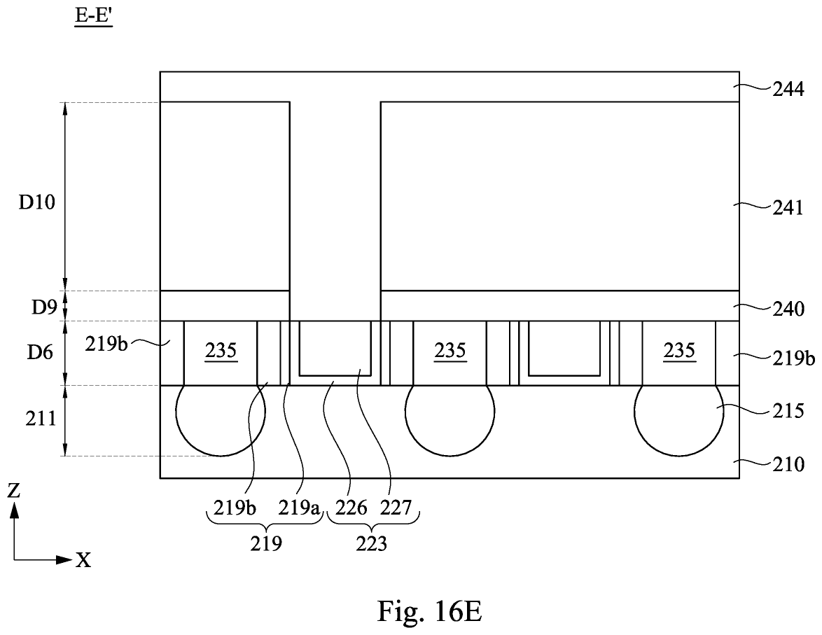

Subsequently, as shown in FIGS. 16A-16E, the contact material 244 may be deposited by chemical vapor deposition (CVD), physical vapor deposition (PVD), sputter deposition, or other techniques suitable for depositing conductive materials. The contact material 244 may include a metal-containing material such as titanium nitride, titanium oxide, argentum (Ag), platinum (Pt), tungsten (W), cobalt (Co), ruthenium (Ru), RuCo, aluminum (Al), copper (Cu), Ru-alloy, W-alloy, Mo-alloy, Cu-alloy, combinations thereof, multi-layers thereof, or the like.

Subsequently, as shown in FIGS. 17A, 17B, and 17D-17F, a planarization process such as a chemical mechanical polish (CMP), an etch-back process, combinations thereof, or the like may be utilized to remove an excess portion of the contact material 244 over the top surface of the ILD layer 241. In some embodiments, the planarization process may (not separately illustrated) be further performed to decrease the thicknesses of the contact material 244 and the ILD layer 241 to a dimension T3 (or thickness), resulting in the source/drain via 245 and the gate via 247 each including a remainder of the contact material 244. In some embodiments, the vertical dimension T3 can be less than the dimension D9 (see FIG. 14B) of the CESL 240 and/or the dimension D10 (see FIG. 14B) of the ILD layer 241. By way of example and not limitation, the vertical dimension T3 can be in a range from about 0.1-30 nm, such as about 0.1, 5, 10, 15, 20, 25, or 30 nm.

In some embodiments, the source/drain via 245 can have a T-shaped top view profile and have a first portion 245a extending in the lengthwise direction of the channel region 214 and a second portion 245b extending in the lengthwise direction of the gate structures 223. As shown in FIG. 17B, the first portion 245a of the source/drain via 245 can overlap with the source/drain contact 235 and the dielectric regions 228 on opposite sides of the source/drain contact 235. In some embodiments, the first portion 245a of the source/drain via 245 may have a lateral dimension T4 (or width) greater than the lateral dimension D7 (see FIG. 13B) of the source/drain contact 235 and/or the lateral dimension D8 (see FIG. 13B) of the dielectric region 228. By way of example and not limitation, the lateral dimension T4 can be in a range from about 0.1 to 100 nm, such as 0.1, 10, 20, 30, 40, 50, 60, 70, 80, 90, or 100 nm.

As shown in FIGS. 17D and 17E, the second portion 245b of the source/drain via 245 can overlap the active region 111 and have a lateral dimension T5 (or width). The lateral dimension T5 may be substantially the same as the lateral dimension D7 (see FIG. 7B) of the source/drain contact 235. In some embodiments, the lateral dimension T5 of the second portion 245b of the source/drain via 245 can be greater than or less than the lateral dimension D7 of the source/drain contact 235. In some embodiments, the lateral dimension T4 of the first portion 245a is greater than the lateral dimension T5 of the second portion 245b. As shown in FIGS. 17B and 17D-17F, the source/drain via 245 can have a top surface 245t coplanar with a top surface 247t of the gate via 247. In other words, the top surface 245t of the source/drain via 245 can be level with the top surface 247t of the gate via 247. In some embodiments, the source/drain via 245 has a vertical dimension T6 (or height) substantially the same as a vertical dimension T7 (or height) of the gate via 247.

Reference is made to FIG. 17C. FIG. 17C is a schematic cross-sectional view of a semiconductor structure 200c corresponding to FIG. 17B according to some embodiments of the present disclosure. While FIG. 17C show an embodiment of a semiconductor structure 200c with different cross-sectional view profiles than the semiconductor structure 200c in FIG. 1B. In addition, the present disclosure may repeat reference numerals and/or letters in the various examples. This repetition is for the purpose of simplicity and clarity and does not in itself dictate a relationship between the various embodiments and/or configurations discussed. Specifically, a liner 249 can be conformally deposited over the ILD layer 241 and in the opening O2 prior to forming the contact material 244, such that after the planarization process as shown in FIG. 17B, the liner 249 can wrap around the source/drain via 245. In some embodiments, the liner 249 may include titanium (Ti), titanium nitride (TiN), tantalum (Ta), tantalum nitride (TaN), or another suitable material. In some embodiments, the liner 249 can be interchangeably referred to a barrier layer.

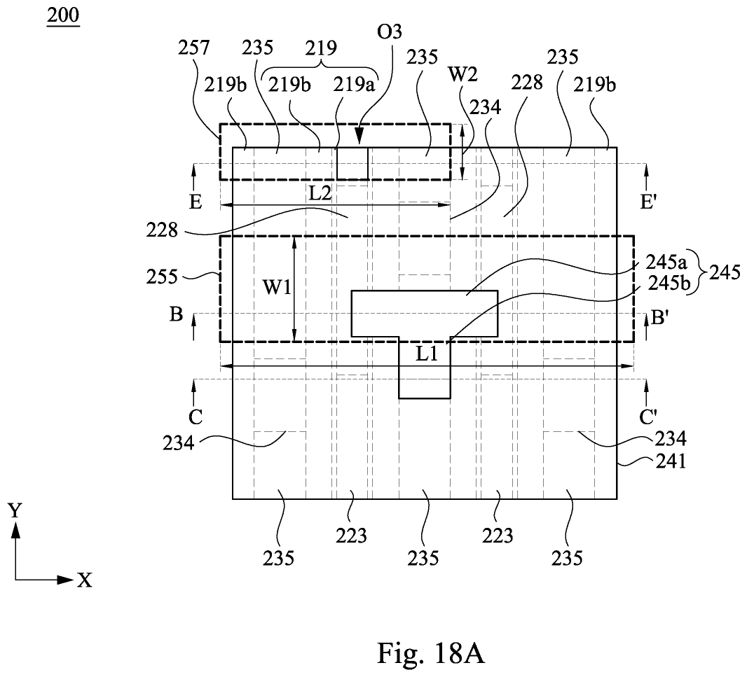

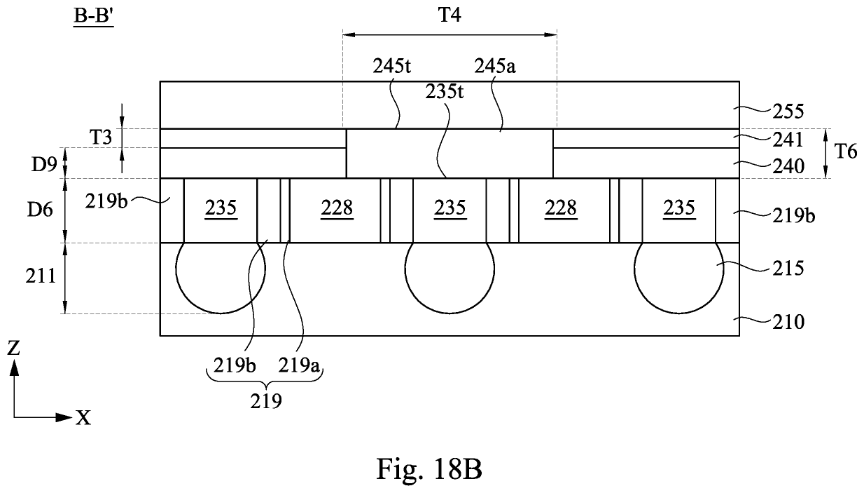

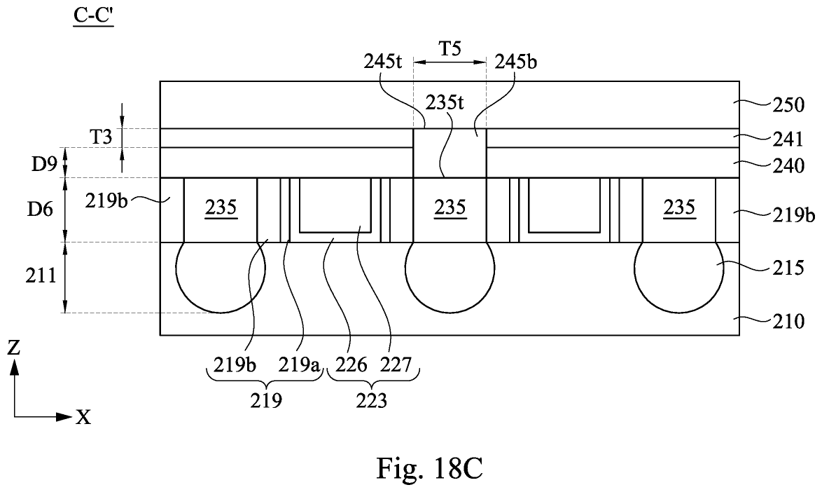

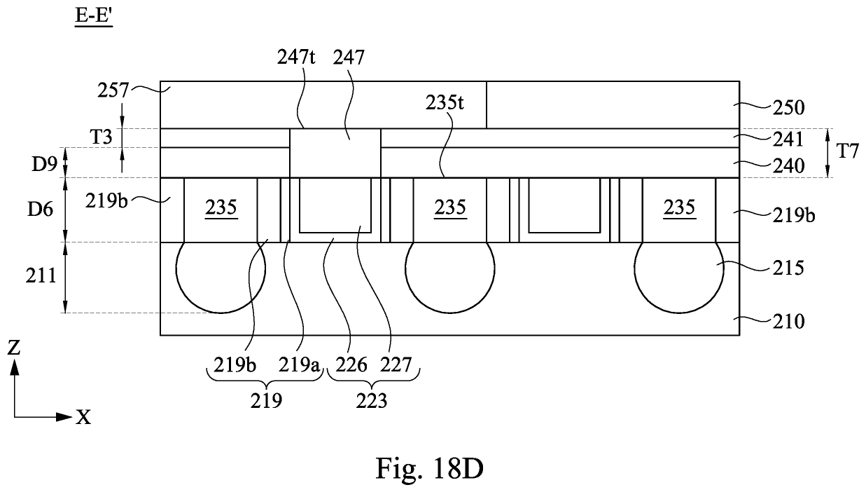

Reference is made to FIGS. 18A-18D. An interconnect structure is formed over the source/drain via 245 and the conductive vias 247. The interconnect structure may include a plurality of metallization layers with a plurality of metal vias, metal line, or other interconnects. The metal line illustrated here just for an example, and the metal line may be otherwise oriented (rotated 90 degrees or at other orientations). The interconnect structure may include metal lines 255 and 257 formed in a first metallization layer. The metal lines 255 and 257 are formed in an IMD (inter-metal dielectric) layer 250. The metal layer 255 can be electrically connected to the source/drain via 245 and act as a power rail (PR), and the metal layer 257 can be electrically connected to the gate via 247.

In some embodiments, by enlarging the volume of the source/drain via 245, the spatial relation and alignment of metal lines 255 and 257 can be further modified. Similar to the FEOL, due to the increased volume of the source/drain via 245, the modification can reduce the overlap area and distance between the metal lines 255 and 257, leading to a reduced effective capacitance (Ceff), such as at least about 3% Ceff reduction in BEOL. To enlarge the volume of the source/drain via 245, the semiconductor structure 200 can provide the T-shaped top view profile for the source/drain via 245. This T-shaped top view profile can maximize the area available for current flow and to optimize the device's electrical properties. One of the steps to achieve the T-shaped view profile for the source/drain via 245 can involve removing its dummy section of the metal layer 257 connecting the gate via 247. By removing this dummy section, the length of the metal layer 257 is shortened. This not only saves space but also allows for the adjacent source/drain via 245 to expand its volume. As the dummy section of the metal layer 257 is removed, it can provide more space for the source/drain via 245 to extend, enhancing its volume.

As shown in FIG. 18A, the metal layer 255 can extend across a first number of the gate structures 223, the metal layer 257 can extend across a second number of the gate structures 223, and the first number is greater than a second number. In other words, the metal layer 257 can remove the dummy section to shorten its length, thereby reducing the space it occupies to expand the volume of the adjacent source/drain via. Specifically, the metal layer 255 connecting to the source/drain via 245 can have a length L1 and a width W1, and the metal layer 257 connecting to the gate via 247 can have a length L2 and a width W2. In some embodiments, the length L2 of the metal layer 257 may be shorter than the length L1 of the metal layer 255, and/or the width W2 of the metal layer 257 may be narrower than the width L1 of the metal layer 255.

In some embodiments, materials of the metal lines 255 and 257 may include Cu, Co, Ru, Pt, Al, W, Ti, TaN, TiN, or any combinations thereof. In some embodiments, the IMD layer 250 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, the metal lines 255 and 257 can be interchangeably referred to as metal tracks.

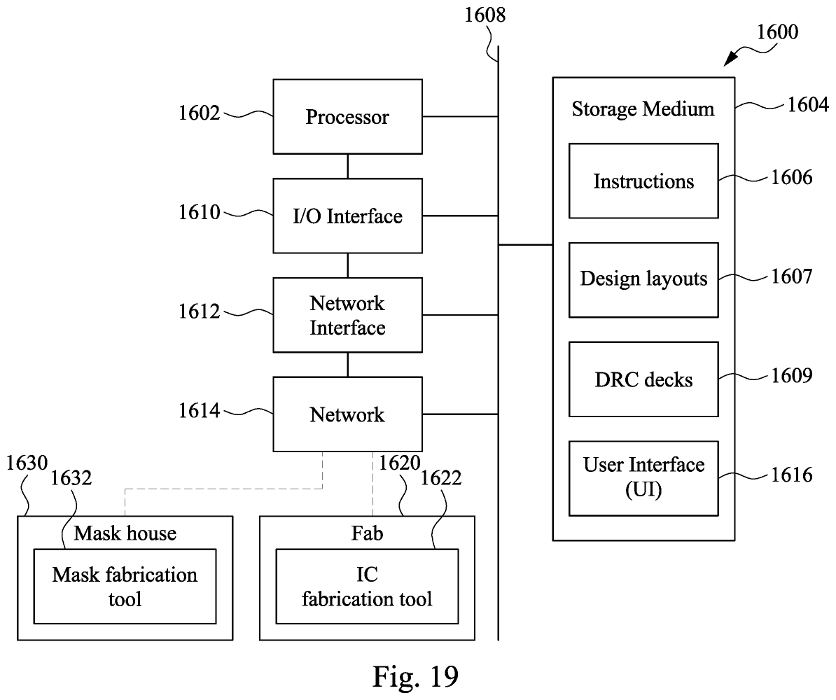

Reference is made to FIG. 19. FIG. 19 is a schematic diagram of an electronic design automation (EDA) system 1600, in accordance with some embodiments. Methods described herein of generating design layouts, e.g., layouts of the integrated circuits of the semiconductor structure as discussed above, in accordance with one or more embodiments, are implementable, for example, using EDA system 1600, in accordance with some embodiments. At least integrated circuit is manufactured by a corresponding layout design similar to the corresponding integrated circuit. For brevity FIGS. 1A-18D are described as corresponding integrated circuits, but in some embodiments, FIGS. 1A-18D also correspond to layout designs with corresponding patterns with corresponding structures, and pattern relationships including alignment, lengths and widths, as well as configurations and layers of a corresponding layout design are similar to the structural relationships and configurations and layers of the corresponding integrated circuit, and similar detailed description will not be described for brevity. In some embodiments, EDA system 1600 is a computing device that is capable of executing one or more automatic placement & routing (APR) operations. The EDA system 1600 including a hardware processor 1602 and a non-transitory, computer-readable storage medium 1604. Computer-readable storage medium 1604, amongst other things, is encoded with, i.e., stores, a set of executable instructions 1606, design layouts 1607, design rule check (DRC) decks 1609 or any intermediate data for executing the set of instructions. Each design layout 1607 may include a graphical representation of an integrated chip, such as for example, a GSII file. Each DRC deck 1609 may include a list of design rules specific to a semiconductor process chosen for fabrication of a design layout 1607. Execution of instructions 1606, design layouts 1607 and DRC decks 1609 by hardware processor 1602 represents (at least in part) an EDA tool which implements a portion or all of, e.g., the methods described herein in accordance with one or more (hereinafter, the noted processes and/or methods).

Processor 1602 is electrically coupled to computer-readable storage medium 1604 via a bus 1608. Processor 1602 is also electrically coupled to an I/O interface 1610 by bus 1608. A network interface 1612 is also electrically connected to processor 1602 via bus 1608. Network interface 1612 is connected to a network 1614, so that processor 1602 and computer-readable storage medium 1604 are capable of connecting to external elements via network 1614. Processor 1602 is configured to execute instructions 1606 encoded in computer-readable storage medium 1604 in order to cause EDA system 1600 to be usable for performing a portion or all of the noted processes and/or methods. In one or more embodiments, processor 1602 is a central processing unit (CPU), a multi-processor, a distributed processing system, an application specific integrated circuit (ASIC), and/or a suitable processing unit.

In one or more embodiments, computer-readable storage medium 1604 is an electronic, magnetic, optical, electromagnetic, infrared, and/or a semiconductor system (or apparatus or device). For example, computer-readable storage medium 1604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1604 includes a compact disk-read only memory (CD-ROM), a compact disk-read/write (CD-R/W), and/or a digital video disc (DVD).

In one or more embodiments, computer-readable storage medium 1604 stores instructions 1606, design layouts 1607 (e.g., layouts of the integrated circuits of the semiconductor structure as discussed previously) and DRC decks 1609 configured to cause EDA system 1600 (where such execution represents (at least in part) the EDA tool) to be usable for performing a portion or all of the noted processes and/or methods. In one or more embodiments, storage medium 1604 also stores information which facilitates performing a portion or all of the noted processes and/or methods.

EDA system 1600 includes I/O interface 1610. I/O interface 1610 is coupled to external circuitry. In one or more embodiments, I/O interface 1610 includes a keyboard, keypad, mouse, trackball, trackpad, touchscreen, and/or cursor direction keys for communicating information and commands to processor 1602.

EDA system 1600 also includes network interface 1612 coupled to processor 1602. Network interface 1612 allows EDA system 1600 to communicate with network 1614, to which one or more other computer systems are connected. Network interface 1612 includes wireless network interfaces such as BLUETOOTH, WIFI, WIMAX, GPRS, or WCDMA; or wired network interfaces such as ETHERNET, USB, or IEEE-1388. In one or more embodiments, a portion or all of noted processes and/or methods, is implemented in two or more EDA systems 1600.

EDA system 1600 is configured to receive information through I/O interface 1610. The information received through I/O interface 1610 includes one or more of instructions, data, design rules, libraries of standard cells, and/or other parameters for processing by processor 1602. The information is transferred to processor 1602 via bus 1608. EDA system 1600 is configured to receive information related to a user interface (UI) 1616 through I/O interface 1610. The information is stored in computer-readable medium 1604 as UI 1616.

Also illustrated in FIG. 19 are fabrication tools associated with the EDA system 1600. For example, a mask house 1630 receives a design layout from the EDA system 1600 by, for example, the network 1614, and the mask house 1630 has a mask fabrication tool 1632 (e.g., a mask writer) for fabricating one or more photomasks (e.g., photomasks used for fabricating integrated circuits of the semiconductor structure as discussed above) based on the design layout generated from the EDA system 1600. An IC fabricator (“Fab”) 1620 may be connected to the mask house 1630 and the EDA system 1600 by, for example, the network 1614. Fab 1620 includes an IC fabrication tool 1622 for fabricating IC chips (e.g., layouts of the integrated circuits of the semiconductor structure with resistor circuits as discussed above) using the photomasks fabricated by the mask house 1630. By way of example and not limitation, the IC fabrication tool 1622 includes one or more cluster tools for fabricating IC chips. The cluster tool may be a multiple reaction chamber type composite equipment which includes a polyhedral transfer chamber with a wafer handling robot inserted at the center thereof, a plurality of process chambers (e.g., CVD chamber, PVD chamber, etching chamber, annealing chamber or the like) positioned at each wall face of the polyhedral transfer chamber; and a loadlock chamber installed at a different wall face of the transfer chamber.

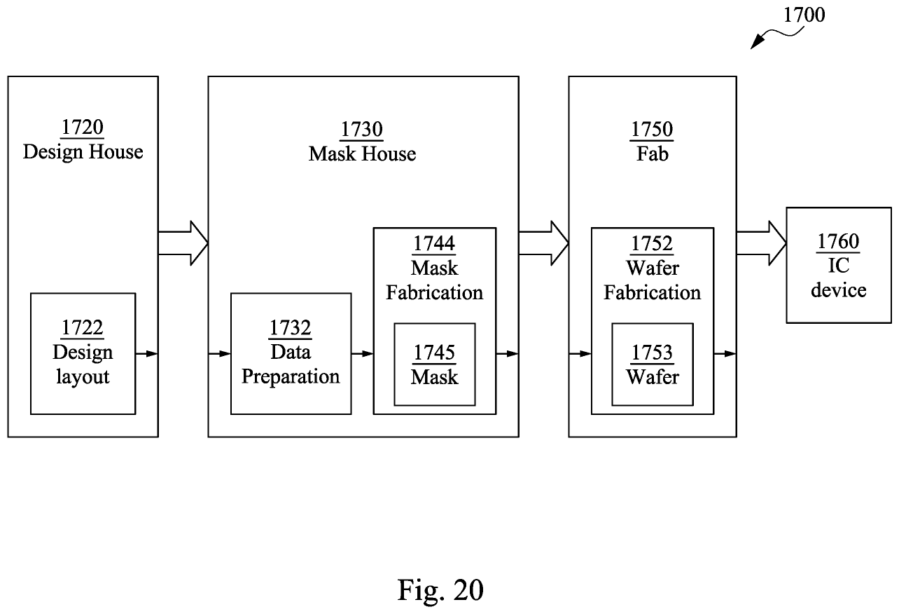

Reference is made to FIG. 20. FIG. 20 is a block diagram of an IC manufacturing system 1700, and an IC manufacturing flow associated therewith, in accordance with some embodiments. In some embodiments, based on one or more design layouts, e.g., layouts of the integrated circuits of the semiconductor structure as discussed above, one or more photomasks and one or more integrated circuits are fabricated using manufacturing system 1700.

In FIG. 20, an IC manufacturing system 1700 includes entities, such as a design house 1720, a mask house 1730, and a Fab 1750, that interact with one another in the design, development, and manufacturing cycles and/or services related to manufacturing ICs 1760. The entities in IC manufacturing system 1700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1720, mask house 1730, and Fab 1750 is owned by a single larger company. In some embodiments, two or more of design house 1720, mask house 1730, and Fab 1750 coexist in a common facility and use common resources.

Design house (or design team) 1720 generates design layouts 1722 (e.g., layouts of the integrated circuits of the semiconductor structure as discussed above). Design layouts 1722 include various geometrical patterns designed for ICs 1760 (e.g., integrated circuits of the semiconductor structure as discussed above). The geometrical patterns correspond to patterns of metal, oxide, or semiconductor layers that make up the various components of ICs 1760 to be fabricated. The various layers combine to form various device features. For example, a portion of design layout 1722 includes various circuit features, such as active regions, passive regions, functional gate structures, resistor structures, gate contacts, resistor contacts, source/drain contacts, and/or metal lines, to be formed on a semiconductor wafer. Design house 1720 implements a proper design procedure to form design layout 1722. The design procedure includes one or more of logic design, physical design or place and route. Design layout 1722 is presented in one or more data files having information of the geometrical patterns and a netlist of various nets. For example, design layout 1722 can be expressed in a GDSII file format or DFII file format.

Mask house 1730 includes data preparation 1732 and mask fabrication 1744. Mask house 1730 uses design layout 1722 (e.g., layout of the integrated circuit of the semiconductor structure as discussed above) to manufacture one or more photomasks 1745 to be used for fabricating the various layers of IC 1760 according to design layout 1722. Mask house 1730 performs mask data preparation 1732, where design layout 1722 is translated into a representative data file (“RDF”). Mask data preparation 1732 provides the RDF to mask fabrication 1744. Mask fabrication 1744 includes a mask writer. A mask writer converts the RDF to an image on a substrate, such as a photomask (reticle) 1745. Design layout 1722 is manipulated by mask data preparation 1732 to comply with particular characteristics of the mask writer and/or rules of fab 1750. In FIG. 20, mask data preparation 1732 and mask fabrication 1744 are illustrated as separate elements. In some embodiments, mask data preparation 1732 and mask fabrication 1744 can be collectively referred to as mask data preparation.

In some embodiments, mask data preparation 1732 includes optical proximity correction (OPC) which uses lithography enhancement techniques to compensate for image errors, such as those that can arise from diffraction, interference, other process effects and the like. OPC adjusts design layout 1722. In some embodiments, mask data preparation 1732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1732 includes a mask rule checker (MRC) that checks design layout 1722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies design layout 1722 diagram to compensate for limitations during mask fabrication 1744, which may undo part of the modifications performed by OPC in order to meet mask creation rules.

In some embodiments, mask data preparation 1732 includes lithography process checking (LPC) that simulates processing that will be implemented by Fab 1750 to fabricate ICs 1760. LPC simulates this processing based on design layout 1722 to create a simulated manufactured integrated circuit, such as IC 1760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine design layout 1722.

After mask data preparation 1732 and during mask fabrication 1744, a photomask 1745 or a group of photomasks 1745 are fabricated based on the design layout 1722. In some embodiments, mask fabrication 1744 includes performing one or more lithographic exposures based on the design layout 1722. In some embodiments, an electron-beam (e-beam) or a mechanism of multiple e-beams is used to form a pattern on a photomask 1745 based on design layout 1722. Photomask 1745 can be formed in various technologies. In some embodiments, photomask 1745 is formed using binary technology. In some embodiments, a mask pattern includes opaque regions and transparent regions. A radiation beam, such as an ultraviolet (UV) beam, used to expose the radiation sensitive material layer (e.g., photoresist) which has been coated on a wafer, is blocked by the opaque regions and transmits through the transparent regions. In one example, a binary mask version of photomask 1745 includes a transparent substrate (e.g., fused quartz) and an opaque material (e.g., chromium) coated in the opaque regions of the binary mask. In another example, photomask 1745 is formed using a phase shift technology. In a phase shift mask (PSM) version of photomask 1745, various features in the pattern formed on the phase shift photomask are configured to have proper phase difference to enhance the resolution and imaging quality. In various examples, the phase shift photomask can be attenuated PSM or alternating PSM. The photomask(s) generated by mask fabrication 1744 is used in a variety of processes. For example, such a mask(s) is used in an ion implantation process to form various doped regions in semiconductor wafer 1753, in an etching process to form various etching regions in semiconductor wafer 1753, and/or in other suitable processes.

Fab 1750 may include wafer fabrication 1752. Fab 1750 is an IC fabrication business that includes one or more manufacturing facilities for the fabrication of a variety of different IC products. In some embodiments, Fab 1750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (BEOL fabrication), and a third manufacturing facility may provide other services for the foundry business.

Fab 1750 uses photomask(s) 1745 fabricated by mask house 1730 to fabricate ICs 1760. Thus, fab 1750 at least indirectly uses design layout(s) 1722 (e.g., layouts of the integrated circuits of the semiconductor structure as discussed above) to fabricate ICs 1760. In some embodiments, wafer 1753 is processed by fab 1750 using photomask(s) 1745 to form ICs 1760. In some embodiments, the device fabrication includes performing one or more photolithographic exposures based at least indirectly on design layout 1722.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a source/drain via over the source/drain region of the transistor that has a T-shaped top view profile (see FIG. 2A), so as to expand the volume of source/drain via. By increasing the volume of the source/drain via, the source/drain via can reduce the contact resistance, such that Rc of source/drain via can be reduced by such as at least about 50%. In addition, by enlarging the volume of the source/drain via, the distance between the gate structure and the source/drain contact can be further modified. Due to the increased volume of the source/drain via, the modification can reduce the overlap area and distance between the gate structure and the source/drain contact, leading to a reduced effective capacitance (Ceff), such as at least about 3% Ceff reduction in FEOL. Furthermore, by enlarging the volume of the source/drain via, the spatial relation and alignment of metal lines over the source/drain via can be further modified. Similar to the FEOL, due to the increased volume of the source/drain via, the modification can reduce the overlap area and distance between the metal lines, leading to a reduced effective capacitance (Ceff), such as at least about 3% Ceff reduction in BEOL.

In some embodiments, a method includes forming a transistor over a substrate, the transistor comprising a channel region, a gate structure over the channel region, and a plurality of source/drain regions on opposite sides of the channel region; forming a source/drain contact over one of the source/drain regions; forming a source/drain via over the source/drain contact, wherein from a top view, the source/drain via has a T-shaped profile, the source/drain via has a first portion extending in a lengthwise direction of the channel region, and a second portion extending in a lengthwise direction of the gate structure. In some embodiments, a top surface of the gate structure is coplanar with a top surface of the source/drain contact. In some embodiments, the method further includes forming a gate via over the gate structure, wherein from a cross-sectional view, the gate via has a same height as the source/drain via. In some embodiments, the method further includes forming a metal line over the gate via, the metal line connecting to the gate via and extending along the lengthwise direction of the channel region, wherein from the top view, the metal line overlaps a first longitudinal side of the source/drain contact and does not overlap a second longitudinal side of the source/drain contact opposite to the first longitudinal side. In some embodiments, the method further includes forming a dielectric layer laterally surrounding the source/drain via and the gate via, wherein the source/drain via is in contact with the dielectric layer. In some embodiments, the method further includes after forming the source/drain contact and prior to forming the source/drain via, forming a barrier layer over the source/drain contact, wherein after forming the source/drain via, the barrier layer wraps around the source/drain via. In some embodiments, the source/drain via comprises tungsten, cobalt, aluminum, platinum, argentum, ruthenium, copper, ruthenium cobalt, ruthenium-alloy, copper-alloy, tungsten-alloy, molybdenum-alloy. In some embodiments, the method further includes forming a dielectric region in the gate structure to cut the gate structure into two separate gate strips, wherein from the top view, the first portion of the source/drain via overlaps with the dielectric region. In some embodiments, from the top view, the second portion of the source/drain via overlaps with the one of the source/drain regions. In some embodiments, the transistor is of a fin-like field-effect transistor device or a gate-all-around transistor.

In some embodiments, a method includes forming first and second channel patterns over a substrate; forming a first gate pattern around the first and second channel patterns; forming a plurality of first source/drain patterns on opposite sides of the first channel pattern, and a plurality of second source/drain patterns on opposite sides of the second channel pattern; forming a first dielectric structure cutting the first gate pattern into separate first and second gate strips, the first dielectric structure being between the first and second channel patterns from a top view; forming a metal contact over one of the first source/drain patterns; forming a metal via over the metal contact, wherein from the top view, the metal via has a first portion extending along a lengthwise direction of the first channel pattern and overlapping with the first dielectric structure. In some embodiments, the first portion of the metal via extends across the first dielectric structure. In some embodiments, the method further includes forming a second gate pattern over the substrate and in parallel with the first gate pattern; forming a second dielectric structure cutting the second gate pattern into separate third and fourth gate strips, wherein from the top view, the first portion of the metal via overlaps with the second dielectric structure. In some embodiments, from the top view, the metal via has a second portion extending along a lengthwise direction of the first gate strip, and the second portion of the metal via forms a L-shaped profile with the first portion of the metal via. In some embodiments, from the top view, the metal via has a second portion extending along a lengthwise direction of the first gate strip, and the second portion of the metal via forms a cross shaped profile with the first portion of the metal via.

In some embodiments, the semiconductor structure includes a substrate, a semiconductive nanostructure, a plurality of epitaxial structures, a first metal contact, and a metal via. The semiconductive nanostructure is over a substrate. The gate is around the semiconductive nanostructure. The epitaxial structures are on opposite sides of the semiconductive nanostructure. The first metal contact is over a first one of the epitaxial structures, in which from a cross sectional view, a top surface of the first metal contact is level with and a top surface of the gate. The metal via is over the first metal contact, in which from a top view, the metal via has a first portion extending along a lengthwise direction of the gate and overlapping with the first one of the epitaxial structures. In some embodiments, the metal via has a second portion extending along a lengthwise direction of the semiconductive nanostructure, and from the top view, the second portion of the metal via forms a T-shaped profile with the first portion of the metal via. In some embodiments, the second portion of the metal via extends across the first metal contact. In some embodiments, the semiconductor structure further includes a gate via over the gate, a first metal line connecting to the gate via, and a second metal line connecting to the metal via, in which the first meal line has a shorter length than the second metal line. In some embodiments, the first metal line has a narrower width than the second metal line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a transistor over a substrate, the transistor comprising a channel region, a gate structure over the channel region, and a plurality of source/drain regions on opposite sides of the channel region;
forming a source/drain contact over one of the source/drain regions; and
forming a source/drain via over the source/drain contact, wherein from a top view, the source/drain via has a T-shaped profile, the source/drain via has a first portion extending in a lengthwise direction of the channel region, and a second portion extending in a lengthwise direction of the gate structure.

2. The method of claim 1, wherein a top surface of the gate structure is coplanar with a top surface of the source/drain contact.

3. The method of claim 1, further comprising:
forming a gate via over the gate structure, wherein from a cross-sectional view, the gate via has a same height as the source/drain via.

4. The method of claim 3, further comprising:
forming a metal line over the gate via, the metal line connecting to the gate via and extending along the lengthwise direction of the channel region, wherein from the top view, the metal line overlaps a first longitudinal side of the source/drain contact and does not overlap a second longitudinal side of the source/drain contact opposite to the first longitudinal side.

5. The method of claim 3, further comprising:
forming a dielectric layer laterally surrounding the source/drain via and the gate via, wherein the source/drain via is in contact with the dielectric layer.

6. The method of claim 1, further comprising:
after forming the source/drain contact and prior to forming the source/drain via, forming a barrier layer over the source/drain contact, wherein after forming the source/drain via, the barrier layer wraps around the source/drain via.

7. The method of claim 1, wherein the source/drain via comprises tungsten, cobalt, aluminum, platinum, argentum, ruthenium, copper, ruthenium cobalt, ruthenium-alloy, copper-alloy, tungsten-alloy, molybdenum-alloy.

8. The method of claim 1, further comprising:
forming a dielectric region in the gate structure to cut the gate structure into two separate gate strips, wherein from the top view, the first portion of the source/drain via overlaps with the dielectric region.

9. The method of claim 1, wherein from the top view, the second portion of the source/drain via overlaps with the one of the source/drain regions.

10. The method of claim 1, wherein the transistor is of a fin-like field-effect transistor device or a gate-all-around transistor.

11. A method, comprising:
forming first and second channel patterns over a substrate;
forming a first gate pattern around the first and second channel patterns;
forming a plurality of first source/drain patterns on opposite sides of the first channel pattern, and a plurality of second source/drain patterns on opposite sides of the second channel pattern;
forming a first dielectric structure cutting the first gate pattern into separate first and second gate strips, the first dielectric structure being between the first and second channel patterns from a top view;
forming a metal contact over one of the first source/drain patterns; and
forming a metal via over the metal contact, wherein from the top view, the metal via has a first portion extending along a lengthwise direction of the first channel pattern and overlapping with the first dielectric structure.

12. The method of claim 11, wherein the first portion of the metal via extends across the first dielectric structure.

13. The method of claim 11, further comprising:
forming a second gate pattern over the substrate and in parallel with the first gate pattern; and
forming a second dielectric structure cutting the second gate pattern into separate third and fourth gate strips, wherein from the top view, the first portion of the metal via overlaps with the second dielectric structure.

14. The method of claim 11, wherein from the top view, the metal via has a second portion extending along a lengthwise direction of the first gate strip, and the second portion of the metal via forms a L-shaped profile with the first portion of the metal via.

15. The method of claim 11, wherein from the top view, the metal via has a second portion extending along a lengthwise direction of the first gate strip, and the second portion of the metal via forms a cross shaped profile with the first portion of the metal via.

16. A semiconductor structure, comprising:
a substrate;
a semiconductive nanostructure over the substrate;
a gate around the semiconductive nanostructure;
a plurality of epitaxial structures on opposite sides of the semiconductive nanostructure;
a first metal contact over a first one of the epitaxial structures, wherein from a cross sectional view, a top surface of the first metal contact is level with and a top surface of the gate; and
a metal via over the first metal contact, wherein from a top view, the metal via has a first portion extending along a lengthwise direction of the gate and overlapping with the first one of the epitaxial structures.

17. The semiconductor structure of claim 16, wherein the metal via has a second portion extending along a lengthwise direction of the semiconductive nanostructure, and from the top view, the second portion of the metal via forms a T-shaped profile with the first portion of the metal via.

18. The semiconductor structure of claim 17, wherein the second portion of the metal via extends across the first metal contact.

19. The semiconductor structure of claim 16, further comprising:
a gate via over the gate;
a first metal line connecting to the gate via; and
a second metal line connecting to the metal via, wherein the first meal line has a shorter length than the second metal line.

20. The semiconductor structure of claim 19, wherein the first metal line has a narrower width than the second metal line.
